(19) United States
(12) Patent Application Publication
(10) Pub. No.: US 2023/0095251 A1
(43) Pub. Date: Mar. 30, 2023

(54) PHOTOSENSITIVE TRANSFER MATERIAL AND METHOD OF PRODUCING THE SAME, FILM, TOUCH PANEL, METHOD OF SUPPRESSING DETERIORATION, AND LAMINATE AND METHOD OF PRODUCING THE SAME

(71) Applicant: FUJIFILM Corporation, Tokyo (JP)

(72) Inventors: Kentaro TOYOOKA, Shizuoka (JP); Keigo UEKI, Shizuoka (JP); Masaya SUZUKI, Shizuoka (JP); Keigo YAMAGUCHI, Shizuoka (JP)

(73) Assignee: FUJIFILM Corporation, Tokyo (JP)

(21) Appl. No.: 17/874,843

(22) Filed: Jul. 27, 2022

(30) Foreign Application Priority Data
Jul. 30, 2021 (JP) 2021-126197

(51) Int. Cl. G06F 3/041; G03F 7/038

(52) U.S. Cl. CPC G06F 3/0412; G03F 7/0387; G06F 2203/04103

(57) ABSTRACT

The present invention relates to: a photosensitive transfer material including a temporary support and a photosensitive layer containing a binder polymer, a polymerizable compound, a photopolymerization initiator, and a compound A, in which a number of hydrophilic groups in the compound A being decreased by an action of light or heat, and the photosensitive layer is transferred to a surface of a metal-containing layer; a method of producing the photosensitive transfer material; a film; a touch panel; a method of suppressing deterioration; a laminate; and a method of producing the film.

### CROSS-REFERENCE TO RELATED APPLICATIONS

This application claims priority from Japanese Patent Application No. 2021-126197, filed Jul. 30, 2021, the disclosure of which is incorporated herein by reference in its entirety.

### BACKGROUND OF THE INVENTION

### 1. Field of the Invention

The present disclosure relates to a photosensitive transfer material and a method of producing the same, a film, a touch panel, a method of suppressing deterioration, and a laminate and a method of producing the same.

### 2. Description of the Related Art

In recent years, in electronic devices such as a mobile phone, a car navigator, a personal computer, a ticket vending machine, or a terminal of the bank, a tablet-type input device is disposed on a surface of a liquid crystal device or the like. In such an electronic device, while referring to an instruction image displayed in an image display region of a liquid crystal device, information corresponding to the instruction image can be input by touching a portion where the instruction image is displayed, with a finger or a touch pen.

The input device described above (hereinafter, also referred to as a “touch panel”) includes a resistance film-type input device, a capacitive input device, and the like. A capacitive input device is advantageous in that a transmittance conductive film may be simply formed on one sheet of substrate. As such a capacitive input device, for example, there is a device in which electrode patterns are extended in directions intersecting each other, and which detects an input position by detecting a change of electrostatic capacity between electrodes, in a case where a finger or the like touches.

For the purpose of protecting electrode patterns or lead wires (for example, metal wires such as copper wires) put together on a frame portion, a transparent resin layer is provided in the capacitive input device. A photosensitive resin composition is used as a material for forming such a transparent resin layer.

As a method of suppressing deterioration of a metal in the related art, a method described in JP2016-001608A is known.

In JP2016-001608A, a method of suppressing deterioration of a metal fiber in a film including a metal fiber and a resin layer that contains a metal additive is disclosed.

Furthermore, in the related art, an optical laminate described in WO2015/143383A is known.

In WO2015/143383A, the optical laminate that includes a conductive film including a silver nanowire or a silver mesh pattern, and that contains a light stabilizer containing a transition metal salt or a transition metal complex is disclosed.

### SUMMARY OF THE INVENTION

Due to migration from the metal, the resistance of a metal may deteriorate. Even though various technologies in the related art including the above-described JP2016-001608A and WO2015/143383A have been studied, there is not enough technology to improve the resistance caused by migration (hereinafter, also referred to as “migration resistance”) of the metal, at present.

The present disclosure has been made in view of such circumstances, and an object to be solved by an embodiment of the present disclosure is to provide a photosensitive transfer material capable of improving migration resistance.

An object to be solved by the other embodiment of the present disclosure is to provide a method of producing the photosensitive transfer material.

An object to be solved by the other embodiment of the present disclosure is to provide a film capable of improving migration resistance.

An object to be solved by the other embodiment of the present disclosure is to provide a touch panel including the film.

An object to be solved by the other embodiment of the present disclosure is to provide a method of suppressing deterioration, by which migration resistance can be improved.

An object to be solved by the other embodiment of the present disclosure is to provide a laminate capable of improving migration resistance.

An object to be solved by the other embodiment of the present disclosure is to provide a method of producing the laminate.

The means for achieving the above-described object includes the following aspects.

<1> A photosensitive transfer material comprising:

a temporary support; and

a photosensitive layer containing a binder polymer, a polymerizable compound, a photopolymerization initiator, and a compound A,

a number of hydrophilic groups in the compound A being decreased by an action of light or heat, and

the photosensitive layer is capable of being transferred to a surface of a metal-containing layer.

<2> The photosensitive transfer material according to <1>, in which the compound A is a blocked isocyanate compound or an isocyanate compound.

<3> The photosensitive transfer material according to <1>, in which the compound A is a cationically polymerizable compound.

<4> The photosensitive transfer material according to <1>, in which the compound A has a structure capable of receiving an electron from an acid group.

<5> The photosensitive transfer material according to <4>, in which the compound A having the structure capable of receiving an electron from an acid group is a nitrogen-containing aromatic compound.

<6> The photosensitive transfer material according to any one of <1> to <5>, in which the metal-containing layer includes a silver nanowire and a hydrophilic compound.

<7> The photosensitive transfer material according to <6>, in which the hydrophilic compound contains a hydroxyl group or an acid group.

<8> A method of producing the photosensitive transfer material according to any one of <1> to <7>, comprising:

preparing the temporary support; and

forming the photosensitive layer on one side of the temporary support.

<9> The method of producing the photosensitive transfer material according to <8>, further comprising modifying a surface on the one side of the temporary support between the preparation of the temporary support and the formation of the photosensitive layer.

<10> A film comprising:

a metal-containing layer; and

a resin layer that contains a binder polymer and a compound A and that is disposed on a surface of the metal-containing layer,

a number of hydrophilic groups in the compound A being decreased by an action of light or heat.

<11> The film according to <10>, in which the compound A is a blocked isocyanate compound or an isocyanate compound.

<12> The film according to <10>, in which the compound A is a cationically polymerizable compound.

<13> The film according to <10>, in which the compound A has a structure capable of receiving an electron from an acid group.

<14> The film according to <13>, in which the compound A having the structure capable of receiving an electron from an acid group is a nitrogen-containing aromatic compound.

<15> The film according to any one of <10> to <14>, in which the metal-containing layer includes a silver nanowire and a hydrophilic compound.

<16> The film according to <15>, in which the hydrophilic compound contains a hydroxyl group or an acid group.

<17> A touch panel comprising the film according to any one of <10> to <16>.

<18> A method of suppressing deterioration of a metal in a film that includes a metal-containing layer and a resin layer that is disposed on a surface of the metal-containing layer and that contains a binder polymer,

in which the resin layer contains a compound A, a number of hydrophilic groups in which being decreased by an action of light or heat.

<19> The method of suppressing deterioration according to <18>, in which the compound A is a blocked isocyanate compound or an isocyanate compound.

<20> The method of suppressing deterioration according to <18>, in which the compound A is a cationically polymerizable compound.

<21> The method of suppressing deterioration according to <18>, in which the compound A has a structure capable of receiving an electron from an acid group.

<22> The method of suppressing deterioration according to <21>, in which the compound A having the structure capable of receiving an electron from an acid group is a nitrogen-containing aromatic compound.

<23> The method of suppressing deterioration according to any one of <18> to <22>, in which the metal-containing layer includes a silver nanowire and a hydrophilic compound.

<24> The method of suppressing deterioration according to <23>, in which the hydrophilic compound contains a hydroxyl group or an acid group.

<25> A laminate comprising the film according to any one of <10> to <16>, the laminate comprising, in the following order:

a substrate having the metal-containing layer on its surface; and

the resin layer.

<26> The laminate according to <25>, in which the compound A is a blocked isocyanate compound or an isocyanate compound.

<27> The laminate according to <25>, in which the compound A is a cationically polymerizable compound.

<28> The laminate according to <25>, in which the compound A has a structure capable of receiving an electron from an acid group.

<29> The laminate according to <28>, in which the compound A having the structure capable of receiving an electron from an acid group is a nitrogen-containing aromatic compound.

<30> The laminate according to any one of <25> to <29>, in which the metal-containing layer includes a silver nanowire and a hydrophilic compound.

<31> The laminate according to <30>, in which the hydrophilic compound contains a hydroxyl group or an acid group.

<32> A method of producing a laminate comprising, in the following order:

transferring at least the photosensitive layer in the photosensitive transfer material according to any one of <1> to <7> to a substrate having the metal-containing layer on a surface thereof;

subjecting the photosensitive layer to a pattern exposure; and

developing the photosensitive layer to form a pattern.

<33> The method of producing a laminate according to <32>, further comprising heating the photosensitive layer after the formation of a pattern.

According to an embodiment of the present disclosure, a photosensitive transfer material capable of improving migration resistance is provided.

According to another embodiment of the present disclosure, a method of producing the photosensitive transfer material is provided.

According to another embodiment of the present disclosure, a film capable of improving migration resistance is provided.

According to another embodiment of the present disclosure, a touch panel including the film is provided.

According to another embodiment of the present disclosure, a method of suppressing deterioration, by which migration resistance can be improved, is provided.

According to another embodiment of the present disclosure, a laminate capable of improving migration resistance is provided.

According to another embodiment of the present disclosure, a method of producing the laminate is provided.

### BRIEF DESCRIPTION OF THE DRAWINGS

FIG. 1 is a schematic cross-sectional view showing an example of a photosensitive transfer material according to the present disclosure.

FIG. 2 is a schematic cross-sectional view showing another example of the photosensitive transfer material according to the present disclosure.

FIG. 3 is a schematic cross-sectional view showing still another example of the photosensitive transfer material according to the present disclosure.

FIG. 4 is a schematic cross-sectional view showing one specific example of a touch panel according to the present disclosure.

FIG. 5 is a schematic cross-sectional view showing another specific example of the touch panel according to the present disclosure.

FIG. 6 is a schematic plane view showing another specific example of the touch panel according to the present disclosure.

FIG. 7 is a cross-sectional view taken along line A-A of FIG. 6.

FIG. 8 is a schematic plane view of a laminate used for an evaluation of migration resistance.

FIG. 9 is a schematic cross-sectional view of the laminate used for the evaluation of migration resistance.

### DESCRIPTION OF THE PREFERRED EMBODIMENTS

Hereinafter, the contents of the present disclosure will be described in detail. The configuration requirements will be described below based on the representative embodiments of the present disclosure, but the present disclosure is not limited to such embodiments.

In the present disclosure, a term “to” showing a range of numerical values is used as a meaning including a lower limit value and an upper limit value disclosed before and after the term.

In a range of numerical values described in stages in the present specification, the upper limit value or the lower limit value described in one range of numerical values may be replaced with an upper limit value or a lower limit value of the range of numerical values described in other stages. In addition, in a range of numerical values described in the present specification, the upper limit value or the lower limit value of the range of numerical values may be replaced with values shown in the examples.

Regarding a term, group (atomic group) of the present disclosure, a term with no description of “substituted” and “unsubstituted” includes both a group not containing a substituent and a group containing a substituent. For example, an “alkyl group” not only includes an alkyl group not containing a substituent (unsubstituted alkyl group), but also an alkyl group containing a substituent (substituted alkyl group).

In addition, in the present disclosure, “% by mass” is identical to “% by weight” and “part by mass” is identical to “part by weight”.

Further, in the present disclosure, a combination of two or more preferred aspects is the more preferred aspects.

In the present disclosure, in a case where a plurality of substances corresponding to components are present in a composition, an amount of each component in the composition means a total amount of the plurality of substances present in the composition, unless otherwise noted.

In the present disclosure, a term “step” not only includes an independent step, but also includes a step, in a case where the step may not be clearly distinguished from the other step, as long as the expected object of the step is achieved.

In the present disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number-average molecular weight (Mn) of the present disclosure, unless otherwise noted, are detected by a gel permeation chromatography (GPC) analysis device using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the present disclosure, unless otherwise specified, a molecular weight of a compound having a molecular weight distribution is a weight-average molecular weight.

In the present disclosure, unless otherwise specified, a ratio of constitutional units of a polymer is a molar ratio.

In the present disclosure, unless otherwise specified, a refractive index is a value at a wavelength of 550 nm measured at 25° C. with an ellipsometer.

Hereinafter, the present disclosure will be described in detail.

Photosensitive Transfer Material

A photosensitive transfer material according to the present disclosure (hereinafter, also simply referred to as a “transfer material”) includes a temporary support and a photosensitive layer that contains a binder polymer and a compound A (simply, referred to as a “compound A”) containing at least one group selected from the group consisting of a metal reducing group and a metal coordinating group.

A photosensitive transfer material according to the present disclosure (hereinafter, also simply referred to as a “transfer material”) includes a temporary support, and a photosensitive layer containing a binder polymer, a polymerizable compound, a photopolymerization initiator, and a compound A, a number of hydrophilic groups in which can be decreased by an action of light or heat (simply, referred to as a “compound A”), and the photosensitive layer is transferred to a surface of a metal-containing layer.

The mechanism by which migration resistance can be improved by using a photosensitive transfer material according to the present disclosure is presumed as follows.

The photosensitive transfer material according to the present disclosure is used to transfer a photosensitive layer on, for example, a metal-containing layer (for example, an electrode material including silver nanowires, copper, or the like) such as a metal conductive material, thereby capable of transferring the compound A, a number of hydrophilic groups in which can be decreased by an action of light or heat from the photosensitive layer (or a cured film thereof) into the metal-containing layer. Therefore, impurities (for example, an ion source, water, a hydrophilic group-containing compound, and the like) in the metal-containing layer can be hydrophobized, so that migration resistance can be improved.

For example, in a case where a metal-containing layer is used as an electrode material, the compound A is transferred from the photosensitive layer (or the cured film thereof) to the electrode material containing impurities such as water and ions, to reduce fragmentation due to deterioration of the electrode material. Therefore, an increase in a resistance value of the electrode can be suppressed, so that excellent migration resistance can be exhibited.

As described above, the inferred mechanism has been explained, but the scope of the present disclosure is not limited to the above inference.

Photosensitive Transfer Material

The photosensitive transfer material according to the present disclosure (hereinafter, also simply referred to as a “transfer material”) includes a temporary support and a photosensitive layer (that is, the photosensitive layer containing a binder polymer, a polymerizable compound, a photopolymerization initiator, and at least one of a compound A having a group capable of being coordinated to a metal or a hygroscopic agent) consisting of a photosensitive composition according to the present disclosure. Such a transfer material can be suitably used for transferring the photosensitive layer on the metal-containing layer.

Hereinafter, the photosensitive transfer material will be described in detail.

Temporary Support

The photosensitive transfer material according to the present disclosure includes a temporary support.

The temporary support is preferably a film and more preferably a resin film. As the temporary support, a film which has flexibility and does not generate significant deformation, contraction, or stretching under pressure or under pressure and heating can be used.

Examples of such a film include a polyethylene terephthalate film (for example, a biaxial stretching polyethylene terephthalate film), a cellulose triacetate film, a polystyrene film, a polyimide film, and a polycarbonate film.

Among these, as the temporary support, a biaxial stretching polyethylene terephthalate film is particularly preferable.

In addition, it is preferable that the film used as the temporary support does not have deformation such as wrinkles or scratches.

From the viewpoint that pattern exposure through the temporary support can be performed, the temporary support preferably has high transparency, and the transmittance at 365 nm is preferably 60% or more and more preferably 70% or more.

The total light transmittance of the temporary support is preferably 80% or more, and more preferably 85% or more.

From the viewpoint of pattern formation during pattern exposure through the temporary support and transparency of the temporary support, it is preferable that the haze of the temporary support is small. Specifically, the haze value of the temporary support is preferably 2% or less, more preferably 0.5% or less, and particularly preferably 0.1% or less.

From the viewpoint of pattern formation during pattern exposure through the temporary support and transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

From the viewpoint of imparting handleability, a layer (lubricant layer) containing fine particles may be provided on the surface of the temporary support. The lubricant layer may be provided on one surface of the temporary support, or on both surfaces thereof. The diameter of each of the particles included in the lubricant layer can be, for example, 0.05 μm to 0.8 μm. In addition, the layer thickness of the lubricant layer can be, for example, 0.05 μm to 1.0 μm.

The thickness of the temporary support is not particularly limited, but is preferably 5 μm to 200 μm. In addition, from the viewpoint of ease of handling and general-purpose properties, the thickness of the temporary support is more preferably 10 μm to 150 μm and still more preferably 10 μm to 50 μm.

Preferred aspects of the temporary support are described in, for example, paragraphs 0017 and 0018 of JP2014-85643A, paragraphs 0019 to 0026 of JP2016-27363A, paragraphs 0041 to 0057 of WO2012/081680A, and paragraphs 0029 to 0040 of WO2018/179370A, and the contents of these publications are incorporated in the present specification.

Examples of the temporary support include LUMIRROR (registered trademark) 16FB40 and LUMIRROR (registered trademark) 16QS62 (16KS40) (all of which are Toray Industries, Inc.), and COSMOSHINE (registered trademark) A4100, COSMOSHINE (registered trademark) A4300, and COSMOSHINE (registered trademark) A8300 (all of which are TOYOBO Co., Ltd.).

In addition, particularly preferred aspects of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 10 μm.

Photosensitive Layer

The photosensitive transfer material according to the present disclosure includes, on the temporary support, the photosensitive layer containing the binder polymer, the polymerizable compound, the photopolymerization initiator, and the compound A, a number of hydrophilic groups in which can be decreased by an action of light or heat.

The photosensitive layer may be a negative-type photosensitive layer or a positive-type photosensitive layer, but is preferably a negative-type photosensitive layer.

Compound A

The photosensitive layer contains the compound A, a number of hydrophilic groups in which can be decreased by an action of light or heat.

The compound A is not particularly limited as long as the compound A has a function of causing a decrease in a number of hydrophilic groups therein by an action of light or heat. The hydrophilic group means a functional group having a high affinity with water, and specifically means a hydroxyl group, an acidic group, and a basic group. Examples of the hydrophilic group include an OH group, a carboxyl group (COOH group), a sulfonic acid group, a phosphoric acid group, an amino group, and the like. Among these, the compound A preferably causes a decrease in an OH group or a carboxyl group (COOH group).

Examples of the compound A include a blocked isocyanate compound and an isocyanate compound. The blocked isocyanate compound and the isocyanate compound can cause these hydrophilic groups to be hydrophobized by a reaction with an OH group and a COOH group.

The isocyanate compound is not particularly limited, but for example, a hexamethylene diisocyanate compound, an isophorone diisocyanate compound, a tolylene diisocyanate compound, a diphenylmethane diisocyanate compound, and the like can be used.

From the viewpoint of storage stability, it is preferable to use a blocked isocyanate compound in which an isocyanate group is protected with a blocking agent. The dissociation temperature of the blocked isocyanate compound is preferably 100° C. to 160° C. and particularly preferably 130° C. to 150° C.

The dissociation temperature of the blocked isocyanate compound according to the present disclosure refers to “temperature at an endothermic peak accompanied with a deprotection reaction of a blocked isocyanate compound, in a case where the measurement is performed by differential scanning calorimetry (DSC) analysis using a differential scanning calorimeter (DSC 6200, manufactured by Seiko Instruments Inc.)”.

Examples of the blocking agent having a dissociation temperature of 100° C. to 160° C. include pyrazole compounds (3,5-dimethylpyrazole, 3-methylpyrazole, 4-bromo-3,5-dimethylpyrazole, 4-nitro-3,5-dimethylpyrazole, and the like), active methylene compounds (diester malonates (dimethyl malonate, diethyl malonate, di-n-butyl malonate, di-2-ethylhexyl malonate) and the like), triazole compounds (1,2,4-triazole, and the like), oxime compounds (form aldoxime, acetoaldoxime, acetooxime, methyl ethyl ketooxime, and cyclohexanoneoxime), salicylic acid esters (methyl salicylate, ethyl salicylate, and the like), phenolic compounds (methyl p-hydroxybenzoate, p-naphthol, and the like), and the like. Among these, pyrazole compounds, malonic acid diester, salicylic acid ester, and phenolic compounds are preferable from the viewpoint of storage stability and low halogenation.

The number of blocked isocyanate groups in the blocked isocyanate compound per molecule is preferably 1 to 10, more preferably 2 to 6, and particularly preferably 3 to 4.

Examples of commercially available blocked isocyanate compounds include Karenz (registered trademark) AOI-SM, AOI-AM, AOI-DM, AOI-BP, and MOI-BP (all of which are manufactured by SHOWA DENKO K.K.).

Examples of commercially available isocyanate compounds include Duranate (registered trademark) TPA-100, 24A-100, and D-101 (all of which are manufactured by Asahi Kasei Corporation), Takenate 500, and Takenate 600 (all of which are manufactured by Mitsui Chemicals, Inc.), and the like.

Examples of the compound A include a cationically polymerizable compound. The cationically polymerizable compound can react with an OH group to hydrophobize the OH group. Examples of the cationically polymerizable compound include an epoxy compound, an oxetane compound, a vinyl ether compound, and the like.

As the epoxy compound, known compounds having an epoxy group can be used without particular limitation. Specific examples of the epoxy compound include a phenol novolac-type epoxy resin, a cresol novolac-type epoxy resin, a trishydroxyphenylmethane-type epoxy resin, a dicyclopentadienephenol-type epoxy resin, a bisphenol-A-type epoxy resin, a bisphenol-F-type epoxy resin, a biphenol type epoxy resin, a bisphenol-A novolac-type epoxy resin, a naphthalene skeleton-containing epoxy resin, an alicyclic epoxy resin, a heterocyclic epoxy resin, and the like.

Examples of commercially available epoxy compounds include Celoxide 2021, PEHPE-3150, and Epolide GT401 (all of which are manufactured by Daicel Corporation), TEPIC-L, TEPIC-H, and TEPIC-S (all of which are manufactured by Nissan Chemical Corporation, Epicron N-740, Epicron N-770, Epicron N-775, Epicron N-660, Epicron N-665, Epicron N-670, Epicron N-673, Epicron N-680, Epicron N-695, Epicron N-665-EXP, Epicron N-672-EXP, and Epicron EXA-7200 (manufactured by DIC Corporation), and the like.

As the oxetane compound, known compounds having an oxetane group can be used without particular limitation. Examples of the oxetane compound include an oxetane compound having a monofunctional oxetane group, an oxetane compound having a bifunctional oxetane group, and an oxetane compound having a tri- or higher functional oxetane group. Oxetane compounds having a bifunctional or trifunctional or higher oxetane group are preferable.

Examples of the oxetane compound in which an oxetane group is monofunctional include (3-ethyloxetane-3-yl)methyl acrylate (for example, OXE-10 manufactured by OSAKA ORGANIC CHEMICAL INDUSTRY LTD.), (3-ethyloxetane-3-yl)methyl methacrylate (for example, OXE-30 manufactured by OSAKA ORGANIC CHEMICAL INDUSTRY LTD.), 3-ethyl-3-hydroxymethyl oxetane (for example, OXT-212 manufactured by Toagosei Co., Ltd.), 3-ethyl-3-(2-ethylhexyloxymethyl)oxetane, 3-ethyl-3-(phenoxymethyl)oxetane, 3-ethyl-3-(2-methacryloxymethyl)oxetane, 3-ethyl-3-{[3-(triethoxysilyl)propoxy]methyl}oxetane, and the like.

Examples of the oxetane compound having a bifunctional oxetane group include 4,4′-bis[(3-ethyl-3-oxetanyl)methoxymethyl]biphenyl (for example, manufactured by UBE Corporation, OXBP), 1,4-bis[(3-ethyl-3-oxetanyl)methoxymethyl]benzene (for example, OXTP manufactured by UBE Corporation), 1,4-bis{[(3-ethyl-3-oxetanyl)methoxy]methyl}benzene (for example, OXT-121 manufactured by Toagosei Co., Ltd.), di[1-ethyl (3-oxetanyl)]methyl ether (for example, OXT-221 manufactured by Toagosei Co., Ltd.), di[1-ethyl (3-oxetanyl)]methyl ether-3-ethyl-3-hydroxymethyloxetane, 3-ethyl-3-(2-ethylhexyloxymethyl)oxetane, 3-ethyl-3-(2-phenoxymethyl)oxetane, 3,7-bis(3-oxetanyl)-5-oxa-nonane, 1,2-bis[(3-ethyl-3-oxetanylmethoxy)methyl]ethane, 1,3-bis[(3-ethyl-3-oxetanylmethoxy)methyl]propane, ethylene glycolbis(3-ethyl-3-oxetanylmethyl)ether, dicyclopentenylbis(3-ethyl-3-oxetanylmethyl)ether, triethylene glycolbis(3-ethyl-3-oxetanylmethyl)ether, tetraethylene glycolbis(3-ethyl-3-oxetanylmethyl)ether, 1,4-bis(3-ethyl-3-oxetanylmethoxy) butane, 1,6-bis(3-ethyl-3-oxetanylmethoxy) hexane, polyethylene glycolbis(3-ethyl-3-oxetanylmethyl)ether, ethylene oxide (EO) modified bisphenol A bis(3-ethyl-3-oxetanylmethyl)ether, propylene oxide (PO) modified bisphenol A bis(3-ethyl-3-oxetanylmethyl)ether, EO-modified hydrogenated bisphenol A bis(3-ethyl-3-oxetanylmethyl)ether, PO-modified hydrogenated bisphenol A bis(3-ethyl-3-oxetanylmethyl)ether, EO-modified bisphenol F(3-ethyl-3-oxetanylmethyl)ether, OXT-191 manufactured by Toagosei Co., Ltd., and the like.

Examples of the oxetane compound having a tri- or higher functional oxetane group include pentaerythritol tris(3-ethyl-3-oxetanylmethyl)ether, pentaerythritol tetrakis(3-ethyl-3-oxetanylmethyl)ether, dipentaerythritol hexa(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexa(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, and the like.

As the vinyl ether compound, any known compound can be used without particular limitation, but a vinyl ether compound having 3 to 35 carbon atoms is preferable. Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexylmethyl vinyl ether, 4-methylcyclohexylmethyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydroflufuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, phenoxypolyethylene glycol vinyl ether, ethyloxetane methyl vinyl ether, dicyclopentadiene vinyl ether, cyclohexanedimethanol vinyl glycidyl ether, tricyclodecane vinyl ether 2-(vinyloxyethoxy) ethyl acrylate, 2-(vinyloxyethoxy) ethyl methacrylate, and the like.

Examples of the polyfunctional vinyl ether include divinyl ethers such as ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, bisphenol A alkylene oxide divinyl ether, and bisphenol F alkylene oxide divinyl ether; trimethylol ethane trivinyl ether, trimethylol propane trivinyl ether, ditrimethylol propane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether, and the like.

From the viewpoint of high sensitivity and availability, diethylene glycol divinyl ether or triethylene glycol divinyl ether is preferable.

Examples of commercially available vinyl ether compounds include triethylene glycol divinyl ether (manufactured by Tokyo Chemical Industry Co., Ltd.), diethylene glycol divinyl ether (manufactured by Tokyo Chemical Industry Co., Ltd.), and the like.

Examples of the compound A include a compound having a structure capable of receiving an electron from an acid group. The compound A having a structure capable of receiving an electron from an acid group may be a compound β having a structure (hereinafter, also referred to as a “specific structure S0”) that causes a decrease in the amount of acid groups by exposure. As a result, an acid group that is a hydrophilic group can be hydrophobized. In a photoexcited state, the compound β is preferably a compound B having a structure capable of receiving an electron from an acid group contained in the compound A (hereinafter, also referred to as a “specific structure S1”).

As described above, the specific structure S0 is a structure that causes a decrease in the amount of acid groups during exposure. The specific structure S0 is preferably a structure that transitions from the ground state to the excited state by exposure and that causes a decrease in acid groups in the excited state. Examples of the specific structure S0 include a structure (specific structure S1) that can receive an electron from an acid group contained in the compound A in a photoexcited state.

The specific structure S0 which the compound β has may be an overall structure constituting the entire compound β or a partial structure constituting a part of the compound β. The compound β may be a high molecular weight compound or a low molecular weight compound, and is preferably a low molecular weight compound. A molecular weight of the compound β that is a low molecular weight compound is preferably less than 5,000, more preferably less than 1,000, still more preferably 65 to 300, and particularly preferably 75 to 250.

The specific structure S0 is preferably a structure (specific structure S1) that can receive an electron from an acid group in a photoexcited state. That is, the compound β is preferably compound B having the structure (specific structure S1) that can receive an electron from an acid group in a photoexcited state.

Hereinafter, the compound β (preferably the compound B) will be described. The compound β (preferably the compound B) is preferably an aromatic compound in that the pattern forming ability is more excellent and/or the moisture permeability of the formed pattern is lower. Here, the aromatic compound is a compound having one or more aromatic rings. Only one aromatic ring may be present in the compound β (preferably the compound B), or a plurality of aromatic rings may be present. In a case where the plurality of aromatic rings are present, the aromatic ring may be present in a side chain of a resin or the like, for example. In the compound β (preferably the compound B), the aromatic ring can be used as a structure (specific structure S1) capable of receiving an electron from an acid group contained in the compound A in a photoexcited state. The aromatic ring may have an overall structure constituting the entire compound β (preferably the compound B), or may have a partial structure constituting a part of the compound β (preferably the compound B). The aromatic ring may be a monocyclic ring or a polycyclic ring, and is preferably a polycyclic ring. The polycyclic aromatic ring is, for example, an aromatic ring formed by condensing a plurality of aromatic ring structures (for example, 2 to 5), and at least one of the plurality of aromatic ring structures preferably has a heteroatom as a ring member atom.

The aromatic ring may be a heteroaromatic ring, and preferably has one or more (for example, 1 to 4) heteroatoms (nitrogen atom, oxygen atom, sulfur atom, and the like) as ring member atoms, and more preferably has one or more nitrogen atoms (for example, 1 to 4) as a ring member atom. The number of ring member atoms of the aromatic ring is preferably 5 to 15. The compound β (preferably the compound B) is preferably a compound having a 6-membered aromatic ring having a nitrogen atom as a ring member atom.

Examples of the aromatic ring include monocyclic aromatic rings such as a pyridine ring, a pyrazine ring, a pyrimidine ring, and a triazine ring; aromatic rings with two condensed rings such as a quinoline ring, an isoquinolin ring, a quinoxaline ring, and a quinazoline ring; aromatic rings with three condensed rings such an acridine ring, a phenanthridine ring, a phenanthroline ring, and a phenazine ring. The compound A having a structure capable of receiving an electron from an acid group may be, for example, a nitrogen-containing aromatic compound having such an aromatic ring.

The aromatic ring may have one or more (for example, 1 to 5) substituents, and examples of the substituents include an alkyl group, an aryl group, a halogen atom, an acyl group, an alkoxycarbonyl group, an arylcarbonyl group, a carbamoyl group, a hydroxy group, a cyano group, an amino group, and a nitro group. In a case where the aromatic ring has two or more substituents, a plurality of substituents may be bonded to each other to form a non-aromatic ring.

It is also preferable that the aromatic ring is directly bonded to the carbonyl group to form an aromatic carbonyl group in the compound β (preferably the compound B). It is also preferable that a plurality of aromatic rings are bonded through a carbonyl group.

It is also preferable that the aromatic ring is bonded to an imide group to form an aromatic imide group in the compound β (preferably the compound B). The imide group in the aromatic imide group may or may not form an imide ring together with the aromatic ring.

In a case where a series of aromatic ring structures in which the plurality of aromatic rings (for example, 2 to 5 aromatic rings) are bonded through a structure selected from the group consisting of a single bond, a carbonyl group, and a multiple bond (for example, a vinylene group which may have a substituent, —C≡C—, —N═N—, or the like) is formed, the entire series of aromatic ring structures is regarded as one specific structure S1.

Further, it is preferable that one or more of the plurality of aromatic rings constituting the series of aromatic ring structures is the heteroaromatic ring.

Specific examples of the compound β (preferably the compound B) include monocyclic aromatic compounds such as pyridine and pyridine derivatives, pyrazine and pyrazine derivatives, pyrimidine and pyrimidine derivatives, and triazine and triazine derivatives; a compound in which two rings are condensed to form an aromatic ring, such as quinoline and quinoline derivatives, isoquinoline and isoquinoline derivatives, quinoxaline and quinoxaline derivatives, and quinazoline and quinazoline derivatives; a compound in which three or more rings are condensed to form an aromatic ring, such as acridine and acridine derivatives, phenanthridine and phenanthridine derivatives, phenanthroline and phenanthroline derivatives, and phenazine and phenazine derivatives.

Among these, the compound β (preferably the compound B) is preferably one or more selected from the group consisting of pyridine and pyridine derivatives, quinoline and quinoline derivatives, and isoquinoline and isoquinoline derivatives, more preferably one or more selected from the group consisting of quinoline and quinoline derivatives, and isoquinoline and isoquinoline derivatives, and still more preferably one or more selected from the group consisting of isoquinoline and isoquinoline derivatives.

These compounds and derivatives thereof may further have a substituent, and as the substituent, an alkyl group, an aryl group, a halogen atom, an acyl group, an alkoxycarbonyl group, an arylcarbonyl group, a carbamoyl group and a hydroxy group, a cyano group, an amino group, or a nitro group is preferable, an alkyl group, an aryl group, a halogen atom, an acyl group, an alkoxycarbonyl group, an arylcarbonyl group, a carbamoyl group, a hydroxy group, a cyano group, or a nitro group is more preferable, an alkyl group, an aryl group, an acyl group, an alkoxycarbonyl group, an arylcarbonyl group, a carbamoyl group, a hydroxy group, a cyano group, or a nitro group is still more preferable, and an alkyl group (for example, an alkyl group having 1 to 10 carbon atoms with a linear or branched chain) is particularly preferable.

In a case where the compound β (preferably the compound B) is a polymer, the polymer may have the specific structure S0 (preferably the specific structure S1) that is bonded to the polymer main chain through a single bond or a linking group. The compound β (preferably the compound B) as a polymer is obtained by, for example, polymerizing a monomer having a heteroaromatic ring (specifically, a (meth)acrylate monomer having a vinyl heteroaromatic ring and/or the specific structure S0 (preferably the specific structure S1, and more preferably a heteroaromatic ring)). As necessary, the compound β may be obtained by copolymerization with another monomer.

Specific examples of the compound β (preferably the compound B) include 5,6,7,8-tetrahydroquinoline, 4-acetylpyridine, 4-benzoylpyridine, 1-phenylisoquinoline, 1-n-butylisoquinoline, 1-n-butyl-4-methylisoquinoline, 1-methylisoquinoline, 2,4,5,7-tetramethylquinoline, 2-methyl-4-methoxyquinoline, 2,4-dimethylquinoline, phenanthridine, 9-methylacridine, 9-phenylacridine, pyridine, isoquinoline, quinoline, acridine, 4-aminopyridine, 2-chloropyridine, and the like.

Examples of commercially available quinolines include 1-methyl-isoquinoline (manufactured by Tokyo Chemical Industry Co., Ltd.), 2,4-dimethylquinoline (manufactured by Tokyo Chemical Industry Co., Ltd.), 1-normalbutylisoquinoline (manufactured by Tokyo Chemical Industry Co., Ltd.), and the like.

The photosensitive layer may contain only one kind of compound A, or may contain two or more kinds of compounds A.

From the viewpoint of migration resistance, a content of the compound A in the photosensitive layer is preferably 0.01% by mass to 10% by mass, more preferably 1.0% by mass to 10% by mass, and still more preferably 1.0% by mass to 6.0% by mass with respect to a total mass of the photosensitive layer.

Binder Polymer

The photosensitive layer contains a binder polymer, and preferably contains the binder polymer and a polymerizable compound from the viewpoint of adhesiveness to a metal-containing layer and hardness of the obtained resin layer on which a pattern has been formed. In addition, in a case where the photosensitive layer does not include a polymerizable compound, the binder polymer preferably includes a binder polymer having a polymerizable group (preferably, an ethylenically unsaturated group).

From the viewpoint of developability, the binder polymer preferably includes an alkali-soluble resin and is more preferably an alkali-soluble resin.

In the present disclosure, the “alkali-soluble” means that the solubility in 100 g of aqueous solution of 1% by mass sodium carbonate at 22° C. is 0.1 g or more.

From a viewpoint of developability, for example, the binder polymer is preferably a binder polymer having an acid value of 60 mgKOH/g or more and more preferably an alkali-soluble resin having an acid value of 60 mgKOH/g or more.

In addition, from the viewpoint that it is easy to form a firmness film by thermally crosslinking with a crosslinking component by heating, for example, the binder polymer is still more preferably a resin (so-called a carboxy group-containing resin) having an acid value of 60 mgKOH/g or more and having a carboxy group, and particularly preferably a (meth)acrylic resin (so-called a carboxy group-containing (meth)acrylic resin) having an acid value of 60 mgKOH/g or more and having a carboxy group.

In a case where the binder polymer is a resin having a carboxy group, for example, the three-dimensional crosslinking density can be increased by adding blocked isocyanate and thermally crosslinking. In addition, in a case where the carboxy group of the resin having a carboxy group is dehydrated and hydrophobized, migration resistance can be improved.

The carboxy group-containing (meth)acrylic resin (hereinafter, also referred to as a “specific polymer A”) having an acid value of 60 mgKOH/g or more is not particularly limited as long as the above-described conditions of acid value are satisfied, and a known (meth)acrylic resin can be appropriately selected and used.

For example, a carboxy group-containing (meth)acrylic resin having an acid value of 60 mgKOH/g or more among polymers described in paragraph 0025 of JP2011-95716A, a carboxy group-containing (meth)acrylic resin having an acid value of 60 mgKOH/g or more among polymers described in paragraphs 0033 to 0052 of JP2010-237589A, and the like can be preferably used as the specific polymer A in the present disclosure.

Here, the (meth)acrylic resin indicates a resin containing at least one of a constitutional unit derived from (meth)acrylic acid or a constitutional unit derived from a (meth)acrylic acid ester.

A total ratio of the constitutional unit derived from (meth)acrylic acid and the constitutional unit derived from (meth)acrylic acid ester in the (meth)acrylic resin is preferably 30% by mol or more and more preferably 50% by mol or more.

The polymer A may have any of a linear structure, a branched structure and an alicyclic structure in the side chain.

The copolymerization ratio of the monomer having a carboxy group in the specific polymer A is preferably 5% by mass to 50% by mass, more preferably 5% by mass to 40% by mass, and still more preferably 10% by mass to 30% by mass with respect to 100% by mass of the specific polymer A.

In addition, from a viewpoint of moisture permeability and hardness after curing, the binder polymer (particularly, the specific polymer A) preferably has a constitutional unit having an aromatic ring.

Examples of a monomer forming the constitutional unit having an aromatic ring include a monomer having an aralkyl group, styrene, and a polymerizable styrene derivative (for example, methylstyrene, vinyltoluene, tert-butoxystyrene, acetoxystyrene, 4-vinylbenzoic acid) styrene dimer, styrene trimer, and the like). Among these, a monomer having an aralkyl group or styrene is preferable.

Examples of the aralkyl group include a substituted or unsubstituted phenylalkyl group, and a substituted or unsubstituted benzyl group is preferable.

Examples of the monomer having a phenylalkyl group other than the benzyl group include phenylethyl (meth)acrylate and the like.

Examples of the monomer having a benzyl group include (meth)acrylate having a benzyl group, for example, benzyl (meth)acrylate, chlorobenzyl (meth)acrylate, and the like; a vinyl monomer having a benzyl group, for example, vinylbenzyl chloride, vinylbenzyl alcohol, and the like. Among these, benzyl (meth)acrylate is preferable.

The constitutional unit having an aromatic ring is preferably a constitutional unit derived from a styrene compound.

In a case where the binder polymer includes the constitutional unit having an aromatic ring, the content of the constitutional unit having an aromatic ring is preferably 5% by mass to 90% by mass, more preferably 10% by mass to 70% by mass, and still more preferably 20% by mass to 50% by mass with respect to a total mass of the binder polymer.

In addition, the binder polymer (particularly the specific polymer A) preferably contains a constitutional unit having an aliphatic cyclic skeleton from a viewpoint of tackiness and hardness after curing. The aliphatic cyclic skeleton may be a monocyclic skeleton or a polycyclic skeleton.

Examples of a monomer forming the constitutional unit having an aliphatic cyclic skeleton include dicyclopentanyl (meth)acrylate, cyclohexyl (meth)acrylate, and isobornyl (meth)acrylate.

Examples of an aliphatic ring included in the constitutional unit having an aliphatic cyclic skeleton include a cyclohexane ring, an isophorone ring, and a tricyclodecane ring.

Among these, a tricyclodecane ring is particularly preferable as the aliphatic ring included in the constitutional unit having an aliphatic cyclic skeleton.

In a case where the binder polymer includes the constitutional unit having an aliphatic cyclic skeleton, the content of the constitutional unit having an aliphatic cyclic skeleton is preferably 5% by mass to 90% by mass, more preferably 10% by mass to 80% by mass, and still more preferably 20% by mass to 70% by mass with respect to a total mass of the binder polymer.

In addition, from the viewpoint of tackiness and hardness after curing, the binder polymer (particularly, the specific polymer A) preferably has a reactive group.

As the reactive group, a radically polymerizable group is preferable, and an ethylenically unsaturated group is more preferable. In addition, in a case where the binder polymer (particularly, the specific polymer A) has an ethylenically unsaturated group, the binder polymer (particularly, the specific polymer A) preferably includes a constitutional unit having an ethylenically unsaturated group in the side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryl group and more preferably a (meth)acryloxy group.

In a case where the binder polymer includes the constitutional unit having an ethylenically unsaturated group, the content of the constitutional unit having an ethylenically unsaturated group is preferably 5% by mass to 70% by mass, more preferably 10% by mass to 50% by mass, and still more preferably 20% by mass to 40% by mass with respect to a total mass of the binder polymer.

Examples of a method of introducing the reactive group into the specific polymer A include a method of reacting an epoxy compound, a blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, a sulfo group, or the like.

Preferred examples of the method of introducing the reactive group into the specific polymer A include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain (for example, a compound A and compound B shown below) can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

As the specific polymer A, the following compounds A and C are preferable, and a compound B is more preferable. The content ratio of each constitutional unit shown below can be appropriately changed according to the purpose. In the compounds A to C, each copolymerization ratio is a mass ratio.

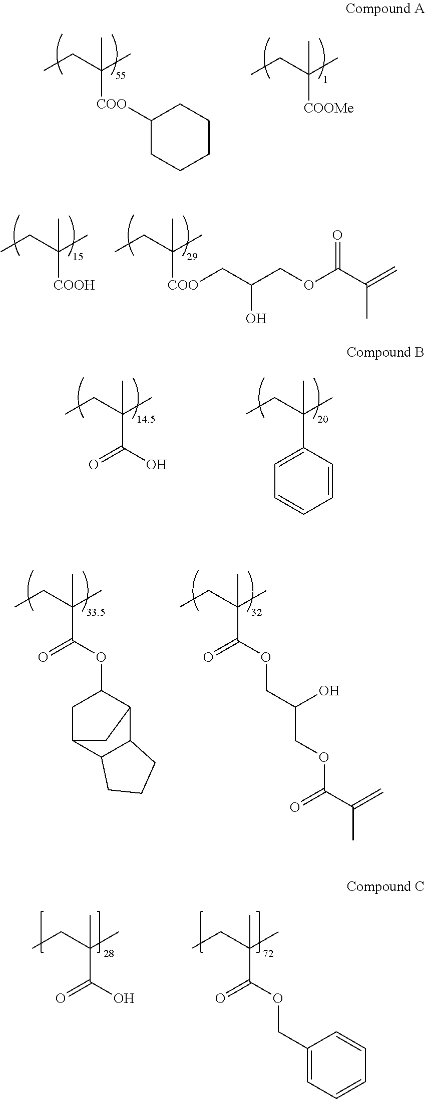

As the specific polymer A, compounds shown below are also preferable. The content ratios (a to d) and the weight-average molecular weight Mw of each of the constitutional units shown below can be appropriately changed according to the purpose.

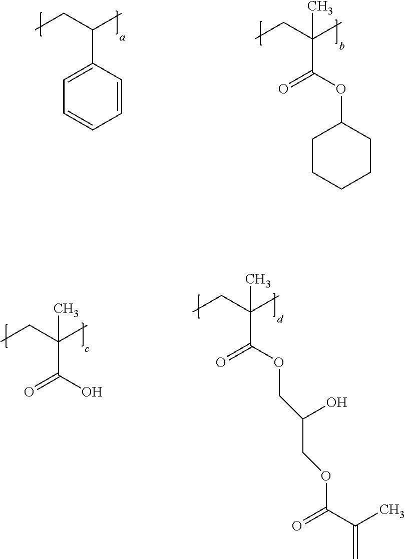

In the above compound, a is preferably 20% by mass to 60% by mass, b is preferably 10% by mass to 50% by mass, c is preferably 5.0% by mass to 25% by mass, and d is preferably 10% by mass to 50% by mass.

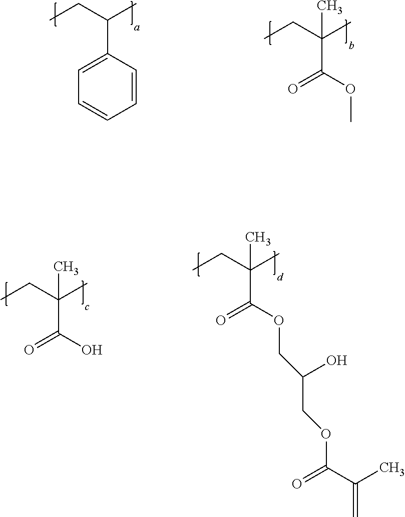

In the above compound, a is preferably 30% by mass to 65% by mass, b is preferably 1.0% by mass to 20% by mass, c is preferably 5.0% by mass to 25% by mass, and d is preferably 10% by mass to 50% by mass.

The weight-average molecular weight (Mw) of the specific polymer A is preferably 10,000 or more, more preferably 10,000 to 100,000, and still more preferably 15,000 to 50,000.

A dispersity (weight-average molecular weight (Mw)/number-average molecular weight (Mn)) of the specific polymer A is preferably 1.0 to 2.0 and more preferably 1.0 to 1.5 from the viewpoint of developability, and preferably 1.8 to 2.8 and more preferably 2.0 to 2.5 from the viewpoint of production suitability.

The acid value of the binder polymer is preferably 60 mgKOH/g to 200 mgKOH/g, more preferably 60 mgKOH/g to 150 mgKOH/g, and still more preferably 60 mgKOH/g to 110 mgKOH/g.

The acid value of the binder polymer is a value measured according to the method described in JIS K0070: 1992.

In a case where the photosensitive layer contains a binder polymer (particularly, specific polymer A) having an acid value of 60 mgKOH/g or more as the binder polymer, a second resin layer which will be described later contains a (meth)acrylic resin having an acid group, in addition to the above-described advantages. Therefore, it is possible to increase interlaminar adhesion between the photosensitive layer and the second resin layer.

The photosensitive layer may contain, as the binder polymer, a polymer (hereinafter, also referred to as a “polymer B”) including a constitutional unit having a carboxylic acid anhydride structure. In a case where the photosensitive layer contains the polymer B, developability and hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5-membered ring to 7-membered ring, more preferably a 5-membered ring or a 6-membered ring, and particularly preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

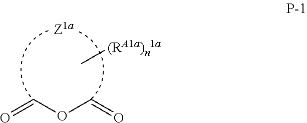

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and particularly preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and particularly preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, still more preferably a constitutional unit derived from an unsaturated alicyclic carboxylic acid anhydride, particularly preferably a constitutional unit derived from maleic anhydride or itaconic anhydride, and most preferably a constitutional unit derived from maleic anhydride.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

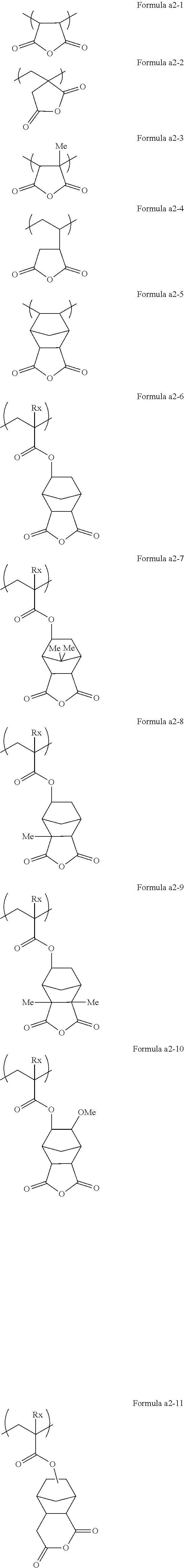

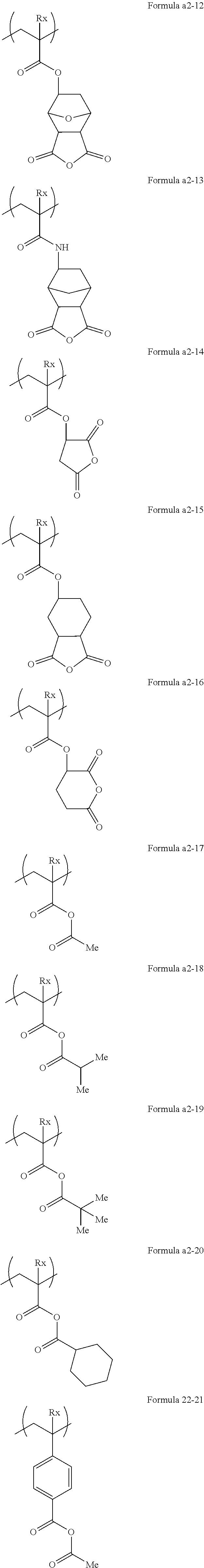

The polymer B may have one constitutional unit having a carboxylic acid anhydride structure alone, or two or more kinds thereof.

The total content of the constitutional unit having a carboxylic acid anhydride structure is preferably 0 mol % to 60 mol %, more preferably 5 mol % to 40 mol %, and particularly preferably 10 mol % to 35 mol % with respect to the total amount of the polymer B.

As the binder polymer, a known binder polymer used for the positive-type photosensitive layer can be used. For example, a polymer containing a constitutional unit having an acid group protected by an acid-decomposable group is suitably mentioned.

As the polymer containing a constitutional unit having an acid group protected by an acid-decomposable group, known polymers can be used, and examples thereof include those described in JP2019-204070A.

From the viewpoint of the migration resistance, a C log P value of the binder polymer is preferably 2.00 or higher, more preferably 2.20 or higher, and particularly preferably 2.50 or higher.

In addition, from the viewpoint of the migration resistance, the C log P value of the binder polymer is preferably 5.00 or lower, more preferably 4.50 or lower, and particularly preferably 4.00 or lower.

The C log P value in the present disclosure is calculated using ChemDraw (registered trademark) Professional (ver. 16.0.1.4) manufactured by PerkinElmer Informatics.

Specifically, for example, the calculation of a polymer is performed by converting the polymer into monomers constituting the polymer. For example, in a case of polyacrylic acid, the calculation is performed by acrylic acid, and in a case of a polyacrylic acid-polymethacrylic acid copolymer (a mass ratio of 50:50), C log P values of acrylic acid and methacrylic acid are calculated, the values are multiplied by the mass ratio (0.5 each in this case), the total value thereof is defined as the C log P value.

The weight-average molecular weight (Mw) of the binder polymer is not particularly limited, but is preferably more than 3,000, more preferably more than 3,000 and 60,000 or less, and still more preferably 5,000 or more and 50,000 or less.

From the viewpoint of patterning properties and reliability, a residual monomer of each constitutional unit in the binder polymer is preferably 1,000 ppm by mass or less, more preferably 500 ppm by mass or less, and particularly preferably 100 ppm by mass or less with respect to the binder polymer. The lower limit is preferably 0.1 ppm by mass or more and more preferably 1 ppm by mass or more.

It is preferable that the amount of residual monomer of the monomer in a case of synthesizing the binder polymer by the polymer reaction is also within the above-described range. For example, in a case where glycidyl acrylate is reacted with a side chain with carboxy group to synthesize the alkali-soluble resin, the content of glycidyl acrylate is preferably within the above-described range.

The amount of the residual monomer can be measured by a known method such as liquid chromatography and gas chromatography.

The photosensitive layer may include only one kind of the binder polymer, or may include two or more kinds thereof.

From the viewpoint of hardness of the cured film and handleability of the photosensitive transfer material, for example, the content of the binder polymer in the photosensitive layer is preferably 10% by mass to 90% by mass, more preferably 20% by mass to 80% by mass, and still more preferably 30% by mass to 70% by mass with respect to a total mass of the photosensitive layer.

Polymerizable Compound

From the viewpoint of photosensitivity and hardness of the obtained resin layer on which a pattern has been formed, the photosensitive layer contains a polymerizable compound.

Examples of the polymerizable compound include an ethylenically unsaturated compound, an epoxy compound, and an oxetane compound. Among these, from the viewpoint of photosensitivity and hardness of a resin layer to be obtained, an ethylenically unsaturated compound is preferable. In some aspects, the polymerizable compound may also be a compound, a number of hydrophilic groups in which can be decreased by an action of light or heat.

The ethylenically unsaturated compound preferably contains a bi- or higher functional ethylenically unsaturated compound.

In the present disclosure, the “bi- or higher functional ethylenically unsaturated compound” means a compound having two or more ethylenically unsaturated groups in one molecule.

As the ethylenically unsaturated group, a (meth)acryloyl group is preferable.

As the ethylenically unsaturated compound, a (meth)acrylate compound is preferable.

From the viewpoint of hardness of the cured film after curing, for example, the ethylenically unsaturated compounds particularly preferably include a bifunctional ethylenically unsaturated compound (preferably, a bifunctional (meth)acrylate compound) and a tri- or higher functional ethylenically unsaturated compound (preferably, a tri- or higher functional (meth)acrylate compound). The upper limit of the number of functional groups of the tri- or higher functional ethylenically unsaturated compound is not particularly limited, but can be, for example, 15 or less functional.

The difunctional ethylenically unsaturated compound is not particularly limited and can be appropriately selected from well-known compounds.

Examples of the difunctional ethylenically unsaturated compound include tricyclodecane dimethanol di(meth)acrylate, tricyclodecane dimethanol di(meth)acrylate, 1,9-nonanediol di(meth)acrylate, and 1,6-hexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,10-decanediol diacrylate (product name: NK ESTER A-DOD-N, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from well-known compounds.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), a mixture of dipentaerythritol hexaacrylate and dipentaerythritol pentaacrylate (KAYARAD DPHA76 manufactured by Nippon Kayaku Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 of Daicel-Allnex Ltd., or the like), and ethoxylated glycerin triacrylate (NK ESTER A-GLY-9E manufactured by Shin-Nakamura Chemical Co., Ltd., or the like).

As the ethylenically unsaturated compound, a urethane (meth)acrylate compound (preferably tri- or higher functional urethane (meth)acrylate compound) is also used.

Examples of the tri- or higher functional urethane (meth)acrylate compound include 8UX-015A (manufactured by Taisei Fine Chemical Co., Ltd.), NK ESTER UA-32P (manufactured by Shin-Nakamura Chemical Co., Ltd.), and NK ESTER UA-1100H (manufactured by Shin-Nakamura Chemical Co., Ltd.).

From the viewpoint of improving developability, the ethylenically unsaturated compound preferably includes an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- to tetra-functional ethylenically unsaturated compound having an acid group [component obtained by introducing a carboxy group to pentaerythritol tri- and tetra-acrylate (PETA) skeleton (acid value: 80 mgKOH/g to 120 mgKOH/g)], and a penta- to hexa-functional ethylenically unsaturated compound having an acid group [component obtained by introducing a carboxy group to dipentaerythritol penta- and hexa-acrylate (DPHA) skeleton (acid value: 25 mgKOH/g to 70 mgKOH/g)].

The tri- or higher functional Ethylenically unsaturated compound containing the acid group may be used in combination with the difunctional ethylenically unsaturated compound containing the acid group, as necessary.

As the ethylenically unsaturated compound containing an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not particularly limited and can be appropriately selected from a known compound.

As the bi- or higher functional ethylenically unsaturated compound having a carboxy group, ARONIX (registered trademark) TO-2349 (manufactured by Toagosei Co., Ltd.), ARONIX (registered trademark) M-520 (manufactured by Toagosei Co., Ltd.), ARONIX (registered trademark) M-510 (manufactured by Toagosei Co., Ltd.), or the like can be preferably used.

As the ethylenically unsaturated compound having an acid group, polymerizable compounds having an acid group, which are described in paragraphs 0025 to 0030 of JP2004-239942A, can be preferably used, and the contents described in this publication are incorporated in the present disclosure.

The photosensitive layer may contain one ethylenically unsaturated compound having an acid group alone, or two or more kinds thereof.

From the viewpoint of developability, and pressure-sensitive adhesiveness of an uncured film that has been obtained, the content of the ethylenically unsaturated compound having an acid group is preferably 0.1% by mass to 30% by mass, more preferably 0.5% by mass to 20% by mass, still more preferably 1% by mass to 10% by mass, and particularly preferably 1% by mass to 5% by mass with respect to a total mass of the photosensitive layer.

In addition, as the polymerizable compound included in the photosensitive layer, the following aspects are also preferably mentioned.

From the viewpoint of the film hardness, the curing property, and the migration resistance of the metal, the polymerizable compound included in the photosensitive layer preferably includes a bifunctional (meth)acrylate compound, a pentafunctional (meth)acrylate compound, and a hexafunctional (meth)acrylate compound.

Furthermore, from the viewpoint of the film hardness, the curing property, and the migration resistance of the metal, as a specific another aspect, the polymerizable compound included in the photosensitive layer preferably includes an alkanediol di(meth)acrylate compound, a pentafunctional (meth)acrylate compound, and a hexafunctional (meth)acrylate compound, and more preferably includes 1,9-nonanediol di(meth)acrylate or 1,10-decanediol di(meth)acrylate, dipentaerythritol hexa(meth)acrylate, and dipentaerythritol penta(meth)acrylate.

The molecular weight of the polymerizable compound is preferably 200 to 3,000, more preferably 250 to 2,600, still more preferably 280 to 2,200, and particularly preferably 300 to 2,200.

The proportion of the content of the polymerizable compound having a molecular weight of 300 or less in the polymerizable compounds included in the photosensitive layer is preferably 30% by mass or less, more preferably 25% by mass or less, and still more preferably 20% by mass or less with respect to the content of all the polymerizable compounds included in the photosensitive layer.

The photosensitive layer may include only one kind of the polymerizable compound, or may include two or more kinds thereof.

The content of the polymerizable compound is preferably 1% by mass to 70% by mass, more preferably 10% by mass to 70% by mass, still more preferably 20% by mass to 60% by mass, and particularly preferably 20% by mass to 50% by mass with respect to a total mass of the photosensitive layer.

In a case where the photosensitive layer includes a bifunctional ethylenically unsaturated compound and a tri- or higher functional ethylenically unsaturated compound, the content of the bifunctional ethylenically unsaturated compound is preferably 10% by mass to 90% by mass, more preferably 20% by mass to 85% by mass, and still more preferably 30% by mass to 80% by mass with respect to the total content of all the ethylenically unsaturated compounds included in the photosensitive layer.

In this case, the content of the trifunctional ethylenically unsaturated compound is preferably 10% by mass to 90% by mass, more preferably 15% by mass to 80% by mass, and still more preferably 20% by mass to 70% by mass with respect to the total content of all the ethylenically unsaturated compounds included in the photosensitive layer.

In this case, the content of the bi- or higher functional ethylenically unsaturated compound is preferably 40% by mass or more and less than 100% by mass, more preferably 40% by mass to 90% by mass, still more preferably 50% by mass to 80% by mass, and particularly preferably 50% by mass to 70% by mass, with respect to a total content of the difunctional ethylenically unsaturated compound and the tri- or higher functional ethylenically unsaturated compound.

In a case of including the bi- or higher functional polymerizable compound, the photosensitive layer may further include a monofunctional polymerizable compound.

In a case where the photosensitive layer includes the bi- or higher functional polymerizable compound, the bi- or higher functional polymerizable compound is preferably a main component of the polymerizable compound included in the photosensitive layer.

In a case where the photosensitive layer includes the bi- or higher functional polymerizable compound, the content of the bi- or higher functional polymerizable compound is preferably 60% by mass to 100% by mass, more preferably 80% by mass to 100% by mass, and particularly preferably 90% by mass to 100% by mass with respect to the total content of all the polymerizable compounds included in the photosensitive layer.

In a case where the photosensitive layer includes the ethylenically unsaturated compound having an acid group (preferably, bi- or higher functional ethylenically unsaturated compound including a carboxy group or a carboxylic acid anhydride thereof), the content of the ethylenically unsaturated compound having an acid group is preferably 1% by mass to 50% by mass, more preferably 1% by mass to 20% by mass, and still more preferably 1% by mass to 10% by mass with respect to a total mass of the photosensitive layer.

Photopolymerization Initiator

The photosensitive layer contains a photopolymerization initiator.

The photopolymerization initiator is not particularly limited and a known photopolymerization initiator can be used.

The photopolymerization initiator may be a radical polymerization initiator or a cationic polymerization initiator, but a radical polymerization initiator is preferable.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-95716A and paragraphs 0064 to 0081 of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methyl-1-pentanone-1-(O-acetyloxime) [product name: IRGACURE (registered trademark) OXE-04, manufactured by BASF SE], 2-(dimethylamino)-2-[4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE (registered trademark) 651, manufactured by BASF SE], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by CHANGZHOU TRONLY NEW ELECTRONIC MATERIALS CO., LTD.), 3-cyclohexyl-1-[9-ethyl-6-(2-furanylcarbonyl)-9H-carbazol-3-yl]-1,2-propanedione-2-(O-acetyloxime) (product name: TR-PBG-326, manufactured by CHANGZHOU TRONLY NEW ELECTRONIC MATERIALS CO., LTD.), 3-cyclohexyl-1-(6-(2-(benzoyloxyimino)hexanoyl)-9-ethyl-9H-carbazol-3-yl)-propan-1,2-dione-2-(O-benzoyloxime) (product name: TR-PBG-391, manufactured by CHANGZHOU TRONLY NEW ELECTRONIC MATERIALS CO., LTD.), API-307 (1-(biphenyl-4-yl)-2-methyl-2-morpholinopropan-1-one, manufactured by Shenzhen UV-ChemTech Ltd.), and the like.

The photosensitive layer may include only one kind of the photopolymerization initiator, or may include two or more kinds thereof.

In a case where the photosensitive layer contains two or more photopolymerization initiators, it is preferable to include an oxime-based photopolymerization initiator and at least one kind selected from the group consisting of an α-aminoalkylphenone-based photopolymerization initiator and an α-hydroxyalkylphenone-based polymerization initiator.

The content of the photopolymerization initiator is not particularly limited, but is preferably 0.1% by mass or more, more preferably 0.5% by mass or more, and still more preferably 1.0% by mass or more with respect to a total mass of the photosensitive layer.

In addition, the content of the photopolymerization initiator is preferably 10% by mass or less and more preferably 5% by mass or less with respect to a total mass of the photosensitive layer.

Heterocyclic Compound Other than Above Compound A

The photosensitive layer may further contain a heterocyclic compound other than the above compound A. The heterocyclic compound contributes to the improvement of adhesiveness to the metal-containing layer and corrosion inhibitory property of the metal.

A heterocyclic ring included in the heterocyclic compound other than the compound A may be either a monocyclic or polycyclic heterocyclic ring.

Examples of a heteroatom included in the heterocyclic compound other than the above compound A include an oxygen atom and the like.

Examples of the heterocyclic ring of the heterocyclic compound other than the compound A include a furan ring, a benzofuran ring, an isobenzofuran ring, a tetrahydrofuran ring, a pyran ring, a benzopyran ring, and the like.

The photosensitive layer may include only one kind of the heterocyclic compound other than the above compound A, or may include two or more kinds thereof.

The content of the heterocyclic compound other than the above compound A is preferably 0.01% by mass to 20% by mass, more preferably 0.1% by mass to 10% by mass, still more preferably 0.3% by mass to 8% by mass, and particularly preferably 0.5% by mass to 5% by mass with respect to a total mass of the photosensitive layer. In a case where the content of the heterocyclic compound other than the above compound A is within the above-described range, the adhesiveness to the metal-containing layer and the corrosion inhibitory property of a metal can be improved.

Thermal Crosslinking Compound

From the viewpoint of hardness of a cured film to be obtained and pressure-sensitive adhesiveness of an uncured film to be obtained, it is preferable that the photosensitive layer contains a thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable. In some aspects, the thermal crosslinking compound may also be a compound a number of hydrophilic groups in which can be decreased by an action of light or heat.

In the present disclosure, in a case where the photosensitive layer includes only a radically polymerizable compound as the photopolymerization initiator, the above-described epoxy compound and the above-described oxetane compound are treated as the thermal crosslinking compound, and in a case of including a cationic polymerization initiator, the above-described epoxy compound and the above-described oxetane compound are treated as the polymerizable compound.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed film tends to decrease, and the function as a protective film tends to be strengthened.

The blocked isocyanate compound refers to a “compound having a structure in which the isocyanate group of isocyanate is protected (so-called masked) with a blocking agent”.

The dissociation temperature of the blocked isocyanate compound is not particularly limited, but is preferably 100° C. to 160° C. and more preferably 130° C. to 150° C.

The dissociation temperature of blocked isocyanate in the present disclosure means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include active methylene compounds [diester malonates (such as dimethyl malonate, diethyl malonate, di-n-butyl malonate, and di-2-ethylhexyl malonate)], and oxime compounds (compound having a structure represented by —C(═N—OH)— in a molecule, such as formaldoxime, acetoaldoxime, acetoxime, methyl ethyl ketoxime, and cyclohexanoneoxime).

Among these, from the viewpoint of preservation stability, the blocking agent having a dissociation temperature of 100° C. to 160° C. is preferably, for example, at least one selected from oxime compounds.

From the viewpoint of improving brittleness of the film and improving the adhesion to a transferred material, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound preferably has a polymerizable group and more preferably has a radically polymerizable group, from the viewpoint of hardness of the cured film.

The polymerizable group is not particularly limited, and a known polymerizable group can be used.

Examples of the polymerizable group include a (meth)acryloxy group, a (meth)acrylamide group, an ethylenically unsaturated group such as styryl group, and an epoxy group such as a glycidyl group.

Among these, as the polymerizable group, from the viewpoint of surface shape of the surface of a cured film to be obtained, a development speed, and reactivity, an ethylenically unsaturated group is preferable, and a (meth)acryloxy group is more preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, manufactured by Asahi Kasei Corporation).

The photosensitive layer may include only one kind of the thermal crosslinking compound, or may include two or more kinds thereof.

The content of the thermal crosslinking compound is preferably 1% by mass to 50% by mass and more preferably 5% by mass to 30% by mass with respect to a total mass of the photosensitive layer.

Surfactant

The photosensitive layer may include a surfactant.

The surfactant is not particularly limited, and a known surfactant can be used.

Examples of the surfactant include surfactants described in paragraph 0017 of JP4502784B and paragraphs 0060 to 0071 of JP2009-237362A.

As the surfactant, a nonionic surfactant, a fluorine-based surfactant, or a silicon-based surfactant is preferable.

Examples of a commercially available product of the fluorine-based surfactant include MEGAFACE F-171, F-172, F-173, F-176, F-177, F-141, F-142, F-143, F-144, F-437, F-444, F-475, F-477, F-479, F-482, F-551-A, F-552, F-554, F-555-A, F-556, F -557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, DS-21 (all of which are manufactured by DIC Corporation), Fluorad FC430, FC431, FC171 (all of which are manufactured by Sumitomo 3M Limited), Surflon S-382, SC-101, SC-103, SC -104, SC-105, SC-1068, SC-381, SC-383, S-393, KH-40 (all of which are manufactured by AGC Inc.), PolyFox PF636, PF656, PF6320, PF6520, PF7002 (all of which are OMNOVA Solutions Inc.), FTERGENT 710FL, 710FM, 610FM, 601AD, 601ADH2, 602A, 215M, 245F, 251, 212M, 250, 209F, 222F, 208G, 710LA, 710FS, 730LM, 650AC, 681 (all of which are manufactured by NEOS COMPANY LIMITED), and the like.

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE DS series manufactured by DIC Corporation (The Chemical Daily (Feb. 22, 2016)); Nikkei Business Daily (Feb. 23, 2016)) such as MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used.

As the fluorine-based surfactant, a block polymer can also be used. As the fluorine-based surfactant, a fluorine-containing polymer compound can be preferably used, the fluorine-containing polymer compound including: a constitutional repeating unit derived from a (meth)acrylate compound having a fluorine atom; and a constitutional repeating unit derived from a (meth)acrylate compound having 2 or more (preferably 5 or more) alkyleneoxy groups (preferably an ethyleneoxy group and a propyleneoxy group).

As the fluorine-based surfactant, a fluorine-containing polymer having an ethylenically unsaturated bond-containing group at a side chain can also be used. MEGAFACE RS-101, RS-102, RS-718K, RS-72-K (all of which are manufactured by DIC Corporation), and the like can be mentioned.

From the viewpoint of improving environmental suitability, the fluorine-based surfactant is preferably a surfactant derived from an alternative material of a compound containing a linear perfluoroalkyl group having 7 or more carbon atoms, such as perfluorooctanoic acid (PFOA) and perfluorooctanesulfonic acid (PFOS).

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (all of which are manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include a linear polymer consisting of a siloxane bond and a modified siloxane polymer containing an organic group introduced into a side chain or a terminal.

Specific examples of the surfactants include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, KF-6002 (all of which are manufactured by Shin-Etsu Chemical Co., Ltd.), TSF-4440, TSF-4300, TSF-4445, TSF-4460, and TSF-4452 (all of which are manufactured by Momentive Performance Materials Co., Ltd.), and BYK307, BYK323, BYK330, and BYK345 (all of which are manufactured by BYK Chemie).

The photosensitive layer may include only one kind of the surfactant, or may include two or more kinds thereof.

The content of the surfactant is preferably 0.01% by mass to 3% by mass, more preferably 0.05% by mass to 1% by mass, and still more preferably 0.1% by mass to 0.8% by mass with respect to a total mass of the photosensitive layer.

Hydrogen Donating Compound

It is preferable that the photosensitive layer includes a hydrogen donating compound.

In the photosensitive layer, the hydrogen donating compound has an action of further improving sensitivity of the photopolymerization initiator with respect to actinic ray, or an action of suppressing inhibition of polymerization of the polymerizable compound by oxygen.

Examples of such a hydrogen donating compound include amines, for example, compounds described in M. R. Sander et al., “Journal of Polymer Society,” Vol. 10, page 3173 (1972), JP1969-20189B (JP-544-20189B), JP1976-82102A (JP-551-82102A), JP1977-134692A (JP-552-134692A), JP1984-138205A (JP-559-138205A), JP1985-84305A (JP-560-84305A), JP1987-18537A (JP-562-18537A), JP1989-33104A (JP-564-33104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-42965B (JP-548-42965B) (tributyl tin acetate and the like), a hydrogen donor described in JP1980-34414B (JP-555-34414B), and a sulfur compound described in JP1994-308727A (JP-H06-308727A) (trithiane and the like).

The photosensitive layer may include only one kind of the hydrogen donating compound, or may include two or more kinds thereof.

For example, from the viewpoint of improving a curing rate by balancing the polymerization growth rate and chain transfer, the content of the hydrogen donating compound is preferably 0.01% by mass to 10% by mass, more preferably 0.03% by mass to 5% by mass, and still more preferably 0.05% by mass to 3% by mass with respect to a total mass of the photosensitive layer.

Photo-Acid Generator

It is preferable that the photosensitive layer includes a photo-acid generator.

The photo-acid generator used in the present disclosure is a compound capable of generating an acid by irradiation with actinic rays such as ultraviolet rays, far ultraviolet rays, X-rays, and electron beams.

The photo-acid generator used in the present disclosure is preferably a compound that is sensitive to actinic rays having a wavelength of 300 nm or more, preferably 300 nm to 450 nm and that generates an acid, but a chemical structure thereof is not limited. A photo-acid generator which is not directly sensitive to actinic rays having a wavelength of 300 nm or more can also be preferably used in combination with a sensitizer as long as it is a compound which is sensitive to actinic rays having a wavelength of 300 nm or more and generates an acid by being used in combination with the sensitizer.

The photo-acid generator used in the present disclosure is preferably a photo-acid generator which generates an acid with a pKa of 4 or less, more preferably a photo-acid generator which generates an acid with a pKa of 3 or less, and particularly preferably a photo-acid generator which generates an acid with a pKa of 2 or less. The lower limit value of the pKa is not particularly limited, but is preferably −10.0 or more.

Examples of the photo-acid generator include an ionic photo-acid generator and a nonionic photo-acid generator.

Examples of the ionic photo-acid generator include onium salt compounds such as diaryliodonium salts and triarylsulfonium salts, and quaternary ammonium salts. Among these, onium salt compounds are preferable, and triarylsulfonium salts and diaryliodonium salts are particularly preferable.

As the ionic photo-acid generator, ionic photo-acid generators described in paragraphs 0114 to 0133 of JP2014-85643A can also be preferably used.

Examples of the nonionic photo-acid generator include trichloromethyl-s-triazines, a diazomethane compound, an imide sulfonate compound, and an oxime sulfonate compound. Among these, from the viewpoint of sensitivity, resolution, and adhesiveness, the photo-acid generator is preferably an oxime sulfonate compound. Specific examples of the trichloromethyl-s-triazines, the diazomethane compound, and the imide sulfonate compound include compounds described in paragraphs 0083 to 0088 of JP2011-221494A.

As the oxime sulfonate compound, those described in paragraphs 0084 to 0088 of WO2018/179640A can be suitably used.

The photosensitive layer may contain one kind of the photo-acid generator alone, or may contain two or more kinds thereof.

From the viewpoint of sensitivity and resolution, the content of the photo-acid generator in the photosensitive layer is preferably 0.1% by mass to 10% by mass and more preferably 0.5% by mass to 5% by mass with respect to a total mass of the photosensitive layer.

Other Components

The photosensitive layer may include components (so-called other components) other than the components described above.

Examples of the other components include particles (for example, metal oxide particles) and a colorant.

In addition, examples of the other components include a thermal polymerization inhibitor described in paragraph 0018 of JP4502784B and other additives described in paragraphs 0058 to 0071 of JP2000-310706A.

In addition, examples of other additives include known additives such as plasticizers, sensitizers, alkoxysilane compounds, basic compounds, ultraviolet absorbers, and rust inhibitors.

Examples of the plasticizers, sensitizers, and alkoxysilane compounds include those described in paragraphs 0097 to 0119 of WO2018/179640A.

Particles

The photosensitive layer may include particles (for example, metal oxide particles; the same applies hereinafter) for the purpose of adjusting refractive index, light-transmitting property, and the like.

The metal of the metal oxide particles also includes semimetal such as B, Si, Ge, As, Sb, or Te.

From the viewpoint of transparency of the cured film, for example, the average primary particle diameter of the particles is preferably 1 nm to 200 nm and more preferably 3 nm to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive layer includes particles, the photosensitive layer may include only one kind of particles having different metal types, sizes, and the like, or may include two or more kinds thereof.

It is preferable that the photosensitive layer does not include particles, or the content of the particles is more than 0% by mass to 35% by mass or less with respect to a total mass of the photosensitive layer; it is more preferable that the photosensitive layer does not include particles, or the content of the particles is more than 0% by mass to 10% by mass or less with respect to a total mass of the photosensitive layer; it is still more preferable that the photosensitive layer does not include particles, or the content of the particles is more than 0% by mass to 5% by mass or less with respect to a total mass of the photosensitive layer; it is even more preferable that the photosensitive layer does not include particles, or the content of the particles is more than 0% by mass to 1% by mass or less with respect to a total mass of the photosensitive layer; and it is particularly preferable that the photosensitive layer does not include particles.

Colorant

The photosensitive layer may include a trace amount of a colorant (pigment, dye, and the like), but for example, from the viewpoint of transparency, it is preferable that the photosensitive layer does not substantially include the colorant.

The content of the colorant is preferably less than 1% by mass and more preferably less than 0.1% by mass with respect to a total mass of the photosensitive layer.

Content of Chloride Ions

From the viewpoint of the migration resistance, a content of chloride ions included in the above-described photosensitive layer is preferably 50 ppm or less, more preferably 20 ppm or less, still more preferably 10 ppm or less, particularly preferably 5 ppm or less, and most preferably 1 ppm or less with respect to a total mass of the photosensitive layer.

In the present disclosure, the content of chloride ions included in the above-described photosensitive layer or in a resin layer described later is measured by the following method.

The photosensitive layer or the resin layer described later is collected as a sample of approximately 100 mg, and approximately 100 mg of the collected sample is dissolved in 5 mL of propylene glycol monomethyl ether acetate. 5 mL of ultrapure water is added thereto, and the mixture is stirred for 2 hours. The mixture is left to stand for 12 hours or more, 1 mL of the aqueous layer is collected, and 9 mL of ultrapure water is added thereto to prepare a sample for measurement.

The prepared sample for measurement is subjected to ion chromatograph according to the measuring device and measuring conditions shown below, thereby measuring and calculating the content of chloride ions.

Ion chromatograph device: IC-2010 (manufactured by Tosoh Corporation)

Analytical column: TSKgel SuperIC-Anion HS

Guard column: TSKgel guardcolumn SuperIC-A HS

Eluent: 1.7 mmol/L NaHCO₃ aqueous solution+1.8 mmol/L Na₂CO₃ aqueous solution

Flow rate: 1.2 mL/min

Temperature: 30° C.

Injection amount: 30 μL

Suppressor gel: TSKgel suppress IC-A

Detection: electrical conductivity (using a suppressor)

Examples of a method of collecting the above-described photosensitive layer used for measuring the content of chloride ions include a method in which a protective film is peeled off, a photosensitive layer on the photosensitive transfer material is laminated on glass, the temporary support is peeled off to transfer the photosensitive layer, and 100 mg of the photosensitive layer is collected.

In addition, examples of a method of collecting the resin layer described later include a method of scraping 100 mg from the resin layer to be collected.

The thickness of the photosensitive layer is not particularly limited, but from the viewpoint of production suitability, reducing the thickness of the entire photosensitive transfer material, improvement of the transmittance of the photosensitive layer or a film to be obtained, and suppression of yellowing of the photosensitive layer or a film to obtained, the thickness of the photosensitive layer is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

The thickness of each layer such as the photosensitive layer is obtained as an average value of 5 random points measured by cross-sectional observation with a scanning electron microscope (SEM).

The refractive index of the photosensitive layer is not particularly limited, but is preferably 1.47 to 1.56, more preferably 1.50 to 1.53, still more preferably 1.50 to 1.52, and particularly preferably 1.51 to 1.52.

Color of Photosensitive Layer

The above-described photosensitive layer is preferably achromatic. In a L*a*b* color system, an a* value of the photosensitive layer is preferably −1.0 to 1.0, and a b* value is preferably −1.0 to 1.0.

Refractive Index of Photosensitive Layer

A refractive index of the photosensitive layer is preferably 1.41 to 1.59 and more preferably 1.47 to 1.56.

Visible Light Transmittance of Photosensitive Layer

A visible light transmittance per 1.0 μm film thickness of the photosensitive layer is preferably 80% or more, more preferably 90% or more, and particularly preferably 95% or more.

As the visible light transmittance, it is preferable that an average transmittance at a wavelength of 400 nm to 800 nm, a minimum transmittance at a wavelength of 400 nm to 800 nm, and a transmittance at a wavelength of 400 nm all satisfy the above transmittance.

Preferable values for the transmittance can be, for example, 87%, 92%, 98%, and the like.

The same applies to the transmittance per 1.0 μm film thickness of the cured film of the photosensitive layer.

Moisture Permeability of Photosensitive Layer

From the viewpoint of device reliability, a moisture permeability of the pattern (the cured film of the photosensitive layer) obtained from the photosensitive layer cured at a film thickness of 40 μm is preferably 500 g/(m²·24 hr) or less, more preferably 300 g/(m²·24 hr) or less, and still more preferably 100 g/(m²·24 hr) or less.

The moisture permeability is measured with a cured film obtained in such a manner that the photosensitive layer is subjected to exposure with an i ray at an exposure amount of 300 mJ/cm², and thereafter, post baking is performed at 145° C. for 30 minutes to cure the photosensitive layer, thereby forming the cured film.

The moisture permeability is measured according to a JIS Z0208 cup method. The above-described moisture permeability is preferably secured under any of test conditions of temperature 40° C./humidity 90%, temperature 65° C./humidity 90%, and temperature 80° C./humidity 95%.

Specific preferable numerical values can include, for example, 80 g/(m²·24 hr), 150 g/(m²·24 hr), 220 g/(m²·24 hr), and the like.

Dissolution Rate of Photosensitive Layer

From the viewpoint of suppressing residue during development, a dissolution rate of the photosensitive layer with respect to a 1.0% aqueous solution of sodium carbonate is preferably 0.01 μm/sec or more, more preferably 0.10 μm/sec or more, and still more preferably 0.20 μm/sec or more. From the viewpoint of an edge shape of the pattern, 5.0 μm/sec or less is preferable, 4.0 μm/sec or less is more preferable, and 3.0 μm/sec or less is still more preferable.

Specific preferable numerical values include, for example, 1.8 μm/sec, 1.0 μm/sec, 0.7 μm/sec, and the like. The dissolution rate of the photosensitive layer with respect to an aqueous solution of 1.0% by mass sodium carbonate per unit time is measured as follows.

Shower development is performed on the photosensitive layer (film thickness within a range of 1.0 to 10 μm), which is formed on the glass substrate and from which the solvent has been sufficiently removed, at 25° C. by using an aqueous solution of 1.0% sodium carbonate by mass until the photosensitive layer is melted out (where, the shower development is performed up to 2 minutes, at longest). The dissolution rate is obtained by dividing the film thickness of the photosensitive layer by the time required for the photosensitive layer to be melted out. In a case where the photosensitive layer is not melted out in 2 minutes, calculation is performed in the same way based on the amount of change in film thickness up to that point.

The dissolution rate of the cured film (the film thickness being within the range of 1.0 μm to 10 μm) of the photosensitive layer with respect to a 1.0% aqueous solution of sodium carbonate is preferably 3.0 μm/sec or less, more preferably 2.0 μm/sec or less, still more preferably 1.0 μm/sec or less, and particularly preferably 0.2 μm/sec or less. The cured film of the photosensitive layer is a film obtained in such a manner that the photosensitive layer is subjected to exposure with an i ray at an exposure amount of 300 mJ/cm².

Specific preferable numerical values can include, for example, 0.8 μm/sec, 0.2 μm/sec, 0.001 μm/sec, and the like.

The development is performed by using a shower nozzle of 1/4 MINJJX030PP manufactured by H.IKEUCHI Co., Ltd., and a shower pressure is 0.08 MPa. Under the above conditions, a shower flow rate per unit time is 1,800 mL/min.

Swelling Ratio of Photosensitive Layer

From the viewpoint of improving pattern formation, a swelling ratio of the photosensitive layer after the exposure with respect to an aqueous solution of 1.0% sodium carbonate by mass is preferably 100% or less, more preferably 50% or less, and still more preferably 30% or less.

The swelling ratio of the photosensitive layer after the exposure with respect to an aqueous solution of 1.0% sodium carbonate by mass is measured as follows.

The photosensitive layer (the film thickness being within the range of 1.0 to 10 μm), which is formed on the glass substrate and from which the solvent has been sufficiently removed, is exposed to 500 mJ/cm² (i ray measurement) with an ultra-high pressure mercury lamp. Each glass substrate is immersed in an aqueous solution of 1.0% by mass sodium carbonate at 25° C., and the film thickness is measured after 30 seconds. Then, a ratio at which a film thickness after immersion increases with respect to the film thickness before immersion is calculated.

Specific preferable numerical values include, for example, 4%, 13%, 25%, and the like.

Foreign Substance in Photosensitive Layer

From the viewpoint of pattern formation, the number of foreign substances each of which has a diameter of 1.0 μm or more in the photosensitive layer is preferably 10 pieces/mm² or less, and more preferably 5 pieces/mm² or less.

The number of foreign substances is measured as follows.

Any 5 regions (1 mm×1 mm) on a surface of the photosensitive layer are visually observed from the normal direction of the surface of the photosensitive layer with an optical microscope, the number of foreign substances each of which has a diameter of 1.0 μm or more in each region is measured, and the results are arithmetically averaged and calculated as the number of foreign substances.

Specific preferable numerical values include, for example, 0 pieces/mm², 1 piece/mm², 4 pieces/mm², 8 pieces/mm², and the like.

Haze of Dissolved Substance in Photosensitive Layer

From the viewpoint of restraining the generation of agglomerates during the development, a haze of a solution obtained in such a manner that a photosensitive layer of 1.0 cm³ is dissolved in 1.0 liter of an aqueous solution of 1.0% by mass sodium carbonate at 30° C. is preferably 60% or less, more preferably 30% or less, still more preferably 10% or less, and particularly preferably 1% or less.

The haze is measured as follows.

First, an aqueous solution of 1.0% by mass sodium carbonate is prepared, and a liquid temperature is adjusted to 30° C. A photosensitive layer of 1.0 cm³ is placed in 1.0 L of an aqueous solution of sodium carbonate. The mixture is stirred at 30° C. for 4 hours while being careful not to mix air bubbles. After stirring, a haze of a solution in which the photosensitive layer is dissolved is measured. The haze is measured using a haze meter (product name “NDH4000”, manufactured by NIPPON DENSHOKU INDUSTRIES Co., Ltd.), a liquid measuring unit, and a liquid measuring cell having an optical path length of 20 mm.

Specific preferable numerical values include, for example, 0.4%, 1.0%, 9%, 24%, and the like.

Second Resin Layer

The photosensitive transfer material according to the present disclosure may further have a second resin layer between the temporary support and the photosensitive layer.

Examples of the second resin layer include a thermoplastic resin layer which will be described later, and an interlayer.

In addition, as the second resin layer the photosensitive transfer material according to the present disclosure may have a thermoplastic resin layer or an interlayer between the temporary support and the photosensitive layer, or may have both a thermoplastic resin layer and an interlayer between the temporary support and the photosensitive layer.

Thermoplastic Resin Layer

The photosensitive transfer material according to the present disclosure may further include a thermoplastic resin layer between a temporary support and a photosensitive layer.

In a case where the photosensitive transfer material further includes a thermoplastic resin layer, air bubbles due to lamination are hardly generated in a case where the photosensitive transfer material is transferred to a substrate to form a film. In a case where this film is used in an image display device, image unevenness is hardly generated and excellent display properties are obtained.

The thermoplastic resin layer preferably has alkali solubility.

The thermoplastic resin layer functions as a cushion material which absorbs ruggedness of the surface of the substrate at the time of transfer.

The ruggedness of the surface of the substrate also includes an image, an electrode, a wiring, and the like which are formed in advance.

The thermoplastic resin layer preferably has properties capable of being deformed in accordance with ruggedness.

The thermoplastic resin layer preferably includes an organic polymer substance described in JP1993-72724A (JP-H05-72724A), and more preferably includes an organic polymer substance having a softening point of approximately 80° C. or lower by a Vicat method (specifically, polymer softening point measurement method using an American Society for Testing and Materials ASTM D1235).

The thickness of the thermoplastic resin layer is preferably, for example, 3 μm to 30 μm, more preferably 4 μm to 25 μm, and still more preferably 5 μm to 20 μm.

In a case where the thickness of the thermoplastic resin layer is 3 μm or more, followability with respect to the ruggedness of the surface of the substrate is improved, and the ruggedness of the surface of the substrate can be effectively absorbed.

In a case where the thickness of the thermoplastic resin layer is 30 μm or less, since the production suitability is more improved, for example, burden of the drying (so-called drying for removing the solvent) in a case of applying and forming the thermoplastic resin layer on the temporary support is further reduced, and the development time of the thermoplastic resin layer after the transfer is further shortened.

The thickness of the thermoplastic resin layer is obtained as an average value of 5 random points measured by cross-sectional observation with a scanning electron microscope (SEM).

The thermoplastic resin layer can be formed by applying and, as necessary, drying a composition for forming a thermoplastic resin layer including a solvent and a thermoplastic organic polymer on the temporary support.

Specific examples of coating and drying methods in the forming method of the thermoplastic resin layer are the same as the specific examples of coating and drying in the forming method of the photosensitive layer, respectively.

The solvent is not particularly limited as long as the solvent dissolves the polymer component forming the thermoplastic resin layer.

Examples of the solvent include organic solvents (for example, methyl ethyl ketone, cyclohexanone, propylene glycol monomethyl ether acetate, n-propanol, and 2-propanol).

The viscosity of the thermoplastic resin layer measured at 100° C. is preferably 1,000 Pa·s to 10,000 Pa·s. In addition, the viscosity of the thermoplastic resin layer measured at 100° C. is preferably lower than the viscosity of the photosensitive layer measured at 100° C.

Interlayer

The photosensitive transfer material according to the present disclosure may further include an interlayer between a temporary support and a photosensitive layer.

In a case where the photosensitive transfer material according to the present disclosure has the thermoplastic resin layer, the interlayer is preferably disposed between the thermoplastic resin layer and the photosensitive layer.

Examples of a component included in the interlayer include at least one polymer selected from the group consisting of polyvinyl alcohol, polyvinylpyrrolidone, and cellulose.

In addition, as the interlayer, a component disclosed in JP1993-72724A (JP-H5-72724A) as a “separation layer” can also be used.

In a case of producing the photosensitive transfer material of an aspect having the thermoplastic resin layer, the interlayer, and the photosensitive layer on the temporary support in this order, for example, the interlayer can be formed by applying and, as necessary, drying a composition for forming an interlayer including a solvent which does not dissolve the thermoplastic resin layer, and the above-described polymer as the component of the interlayer.

Specifically, first, the composition for forming a thermoplastic resin layer is applied and dried on the temporary support to form the thermoplastic resin layer. Next, the composition for forming an interlayer is applied on the formed thermoplastic resin layer and dried as necessary to form the interlayer. Next, a photosensitive composition including an organic solvent is applied on the formed interlayer and dried to form the photosensitive layer. The organic solvent included in the photosensitive composition is preferably an organic solvent which does not dissolve the interlayer.

Specific examples of coating and drying methods in the forming method of the interlayer are the same as the specific examples of coating and drying in the forming method of the photosensitive layer, respectively.

Refractive Index Adjusting Layer

The photosensitive transfer material according to the present disclosure may further have a refractive index adjusting layer between the photosensitive layer and the protective film.

The refractive index adjusting layer is not limited, and a known refractive index adjusting layer can be applied. Examples of a material contained in the refractive index adjusting layer include a binder and particles.

The binder is not limited, and a known binder can be applied. Examples of the binder include the above-described binder polymer.

The particles are not limited, and known particles can be applied. Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, the refractive index adjusting layer preferably contains a metal oxidation inhibitor. In a case where the refractive index adjusting layer contains a metal oxidation inhibitor, oxidation of metal in contact with the refractive index adjusting layer can be suppressed.

Preferred examples of the metal oxidation inhibitor include a compound having an aromatic ring including a nitrogen atom in the molecule. Specific examples of the metal oxidation inhibitor include imidazole, benzimidazole, tetrazole, mercaptothiadiazole, and benzotriazole.

The refractive index of the refractive index adjusting layer is preferably 1.50 or more, more preferably 1.55 or more, and particularly preferably 1.60 or more.

In addition, the upper limit of the refractive index of the refractive index adjusting layer is not particularly limited, but is preferably 2.10 or less and more preferably 1.85 or less.

The thickness of the refractive index adjusting layer is preferably 500 nm or less, more preferably 110 nm or less, and particularly preferably 100 nm or less.

In addition, the thickness of the refractive index adjusting layer is preferably 20 nm or more and more preferably 50 nm or more.

The thickness of the refractive index adjusting layer is obtained as an average value of 5 random points measured by cross-sectional observation with a scanning electron microscope (SEM).

A method of forming the refractive index adjusting layer is not limited, and a known method can be applied. Examples of the method of forming the refractive index adjusting layer include a method using a composition for a refractive index adjusting layer. For example, the composition for a refractive index adjusting layer is applied on an object to be coated, and the composition is dried as necessary, thereby capable of forming a refractive index adjusting layer.

Examples of a method of producing the composition for a refractive index adjusting layer include a method of mixing the above-described components and a solvent. The mixing method is not limited, and a known method can be applied.

The solvent is not limited, and a known solvent can be applied. Examples of the solvent include water, and organic solvents described in the above section of “a method of forming the photosensitive layer”.

As the coating method and drying method, the coating method and drying method described in the above section of “method of forming the photosensitive layer” can be applied, respectively.

Antistatic Layer

The photosensitive transfer material according to the present disclosure may further include an antistatic layer between the photosensitive layer and the protective film or between the photosensitive layer and the temporary support. Since the photosensitive transfer material according to the present disclosure has an antistatic layer, it is possible to suppress generation of static electricity in a case of peeling off the film or the like disposed on the antistatic layer, and also to suppress generation of static electricity due to rubbing against equipment or other films. As a result, for example, it is possible to suppress the occurrence of defects in electronic devices.

The antistatic layer is preferably disposed between the temporary support and the photosensitive layer from the viewpoint of suppressing the generation of static electricity.

The antistatic layer is a layer having antistatic properties and contains at least an antistatic agent. The antistatic agent is not limited, and a known antistatic agent can be used.

The antistatic layer preferably contains, as the antistatic agent, at least one compound selected from the group consisting of an ionic liquid, an ionic conductive polymer, an ionic conductive filler, and a conductive polymer (also, referred to as a “conductive polymer”).

The ionic liquid is preferably an ionic liquid composed of a fluoroorganic anion and an onium cation.

Examples of the ionic conductive polymer include an ionic conductive polymer obtained by polymerizing or copolymerizing a monomer having a quaternary ammonium base. As a counter ion of the quaternary ammonium base, non-halogen ions are preferable. Examples of the non-halogen ion include sulfonate anions and carboxylate anions.

Examples of the ionic conductive filler include tin oxide, antimony oxide, indium oxide, cadmium oxide, titanium oxide, zinc oxide, indium, tin, antimony, gold, silver, copper, aluminum, nickel, chromium, titanium, iron, cobalt, copper iodide, indium oxide/tin oxide (ITO), and antimony oxide/tin oxide (ATO).

Examples of the conductive polymer include polythiophene, polyaniline, polypyrrole, polyethyleneimine, and arylamine-based polymers. Specific examples of the conductive polymer include (3,4-ethylenedioxythiophene)-poly(styrene sulfonic acid).

Among the above examples, the antistatic agent is preferably polythiophene. As the polythiophene, a polymer compound including poly(3,4-ethylenedioxythiophene) (PEDOT) is preferable, and a conductive polymer consisting of poly(3,4-ethylenedioxythiophene) and polystyrene sulfonic acid (hereinafter, abbreviated as “PEDOT/PSS”) is particularly preferable.

The antistatic layer may contain only one kind of antistatic agent, or may contain two or more kinds of antistatic agents.

From the viewpoint of antistatic properties, the content of the antistatic agent is preferably 0.1% by mass to 100% by mass with respect to a total mass of a layer including the antistatic layer. In a case where the antistatic agent is a solvent-dispersed antistatic agent, the content of the antistatic agent is more preferably 1% by mass to 10% by mass and particularly preferably 3% by mass to 10% by mass with respect to a total mass of the antistatic layer. In a case where the antistatic agent is not a solvent-dispersed antistatic agent, the content of the antistatic agent is more preferably 60% by mass to 100% by mass and particularly preferably 70% by mass to 100% by mass with respect to a total mass of the antistatic layer.

The antistatic layer may further contain a component other than the antistatic agent as necessary. Examples of components other than the antistatic agents include, for example, a binder polymer (such as polyvinylpyrrolidone, polyvinyl alcohol, or an acrylic resin), a curable component (such as a polymerizable compound or a photopolymerization initiator), and a surfactant.

The average thickness of the antistatic layer is preferably 1 μm or less, more preferably 0.6 μm or less, still more preferably 0.4 μm or less, and particularly preferably 0.2 μm or less. In a case where the average thickness of the antistatic layer is 1 μm or less, haze can be reduced. The lower limit of the thickness of the antistatic layer is not limited. From the viewpoint of production suitability, the average thickness of the antistatic layer is preferably 0.01 μm or more. The average thickness of the antistatic layer is the arithmetic mean of thicknesses of the five points measured by cross-sectional observation with a scanning electron microscope (SEM).

Examples of the method of forming the antistatic layer include a method using a composition for an antistatic layer. For example, a method of applying a composition for an antistatic layer on an object to be coated (for example, the temporary support or the photosensitive layer) can be mentioned. Examples of the coating method include a printing method, a spray coating method, a roll coating method, a bar coating method, a curtain coating method, a spin coating method, and a die coating method (that is, a slit coating method). Among the above, a die coating method is preferable as the coating method.

In the method of forming an antistatic layer, the photosensitive composition applied on the object to be coated may be dried, as necessary. Examples of the drying method include natural drying, heating drying, and drying under reduced pressure.

Impurities and the Like

It is preferable that the amount of impurities contained in each of the photosensitive layer, the second resin layer, the refractive index adjusting layer, and the antistatic layer is small.

Specific Examples of the impurities include sodium, potassium, magnesium, calcium, iron, manganese, copper, aluminum, titanium, chromium, cobalt, nickel, zinc, tin, and ions of these.

The content of impurities in each layer is preferably 80 ppm or less, more preferably 10 ppm or less, and still more preferably 2 ppm or less on a mass basis. The lower limit is not particularly limited, but the content of impurities in each layer may be 1 ppb or more or 0.1 ppm or more on a mass basis.

Examples of a method of keeping the impurities in the above-described range include selecting a raw material having a low content of impurities as a raw material for each layer, preventing the impurities from being mixed in a case of forming each layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

It is preferable that the content of compounds such as benzene, formaldehyde, trichloroethylene, 1,3-butadiene, carbon tetrachloride, chloroform, N,N-dimethylformamide, N,N-dimethylacetamide, and hexane is low in each layer. The content of these compounds in each layer is preferably 100 ppm or less, more preferably 20 ppm or less, and still more preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of improving reliability and laminating property, the content of water in each layer is preferably 0.01% by mass to 1.0% by mass and more preferably 0.05% by mass to 0.5% by mass.

Protective Film

The photosensitive transfer material according to the present disclosure may further comprise a protective film on an opposite side of the photosensitive layer to the temporary support-provided side.

The above-described protective film is preferably an outermost layer on an opposite surface to the temporary support-provided side in the photosensitive transfer material according to the present disclosure.

Examples of the protective film include a polyethylene terephthalate film, a polypropylene film, a polystyrene film, and a polycarbonate film.

As the protective film, for example, films described in paragraphs 0083 to 0087 and 0093 of JP2006-259138A may be used.

The thickness of the protective film is preferably 1 μm to 100 μm, more preferably 5 μm to 50 μm, still more preferably 5 μm to 40 μm, and particularly preferably 15 μm to 30 μm. The thickness of the protective film is preferably 1 μm or more in terms of excellent mechanical hardness and is preferably 100 μm or less in terms of relatively low cost.

The protective film is also available as ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., or LUMIRROR (registered trademark) 16QS62 (16KS40) manufactured by Toray Industries, Inc.

In order to make it easier to peel off the protective film from the photosensitive layer or the refractive index adjusting layer, it is preferable that the adhesive force between the protective film and the photosensitive layer or the refractive index adjusting layer is smaller than the adhesive force between the temporary support and the photosensitive layer.

The protective film preferably has 5 pieces/m² or less of the number of fisheyes with a diameter of 80 μm or more in the protective film. The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles included in the protective film being transferred to the photosensitive layer or a metal such as a conductive layer.

In the protective film, from the viewpoint of imparting take-up property, the arithmetic average roughness Ra on a surface opposite to a surface in contact with the photosensitive layer or the refractive index adjusting layer is preferably 0.01 μm or more, more preferably 0.02 μm or more, and still more preferably 0.03 μm or more. On the other hand, the arithmetic average roughness Ra is preferably less than 0.50 μm, more preferably 0.40 μm or less, and still more preferably 0.30 μm or less.

In the protective film, from the viewpoint of suppressing defects during transfer, the surface roughness Ra on the surface in contact with the photosensitive layer or the refractive index adjusting layer is preferably 0.01 μm or more, more preferably 0.02 μm or more, and still more preferably 0.03 μm or more. On the other hand, the arithmetic average roughness Ra is preferably less than 0.50 μm, more preferably 0.40 μm or less, and still more preferably 0.30 μm or less.

Metal-Containing Layer

The photosensitive layer of the photosensitive transfer material is transferred to a surface of the metal-containing layer.

The metal is not particularly limited, and examples thereof preferably include a metal conductive material. As the metal conductive material, a known metal conductive material can be used.

Examples of the metal include Al, Zn, Cu, Fe, Ni, Cr, Mo, Ag, Au, and the like. Among these, Au, Ag, or Cu is preferably contained, Au or Ag is more preferably contained, and Ag is particularly preferable.

In addition, as the metal, metal fibers are preferable, silver fibers are more preferable, and silver nanowires are particularly preferable. In a case of adopting the above aspect, the deterioration is more likely to occur under moisture-heat conditions, so that the effect in the present disclosure can be further exhibited.

The shape of the metal is not particularly limited, and may be provided as a layer on one entire surface of the above-described substrate, or may have a desired patterned shape. Examples thereof include a mesh-shaped transparent electrode shape, and a wire shape such as a lead wire (so-called lead-out wire) disposed on a frame portion of the touch panel.

Among these, the metal preferably contains metal fibers, and is particularly preferably a layer containing metal fibers (metal fiber layer). In addition, a layer containing the above-described metal fibers preferably has a desired patterned shape.

The metal may be metal fine particles (for example, silver, copper, nickel, zinc oxide, tin oxide, indium oxide, and the like).

The metal-containing layer may contain silver nanowires and a hydrophilic compound. Even though the metal-containing layer contains a hydrophilic compound as described above, excellent migration resistance can be obtained by using the photosensitive transfer material according to the present disclosure.

The hydrophilic compound is not particularly limited and may contain, for example, a hydroxyl group or an acid group.

The metal-containing layer may contain a carbon-based conductive material (for example, carbon nanotubes, carbon nanofibers, or graphene), a conductive polymer (for example, poly(3,4-ethylenedioxythiophene) doped with poly(4-styrene sulfonic acid), polyaniline, or the like), and the like.

Examples of the shape of the metal fibers include a cylindrical shape, a rectangular parallelepiped shape, and a columnar shape having a polygonal cross-section. The metal fibers preferably have at least one shape of a cylindrical shape or a columnar shape having a polygonal cross-section in applications where high transparency is required.

The cross-sectional shape of the silver nanowires can be observed using, for example, a transmission electron microscope (TEM).

The diameter (so-called minor axis length) of the metal fibers is not particularly limited, but from the viewpoint of transparency, for example, is preferably 50 nm or less, more preferably 35 nm or less, and still more preferably 20 nm or less.

From the viewpoint of oxidation resistance and migration resistance, the lower limit of the diameter of the metal fibers is preferably, for example, 5 nm or more.

The length (so-called major axis length) of the metal fibers is not particularly limited, but from the viewpoint of conductivity, for example, is preferably 5 μm or more, more preferably 10 μm or more, and still more preferably 30 μm or more.

From the viewpoint of suppressing formation of aggregates in the producing process, the upper limit of the length of the metal fibers is preferably, for example, 1 mm or less.

The diameter and length of the metal fibers can be measured using, for example, a transmission electron microscope (TEM) or an optical microscope.

Specifically, the diameter and length of 300 randomly selected silver nanowires are measured from the metal fibers magnified and observed using a transmission electron microscope (TEM) or an optical microscope. Values obtained by arithmetically averaging the measured values are defined as the diameter and length of the silver nanowires.

The content of the metal fibers in the metal fiber layer (an example of the metal-containing layer) is not particularly limited, but from the viewpoint of transparency and conductivity, is preferably 1% by mass to 99% by mass and more preferably 10% by mass to 95% by mass with respect to a total mass of the metal fiber layer.

The metal-containing layer may include a binder (also referred to as a “matrix”), as necessary.

The binder is a solid material in which the metal is dispersed or embedded.

Examples of the binder include polymer materials and inorganic materials.

As the binder, a material having light-transmitting property is preferable.

Examples of the polymer material include (meth)acrylic resins [for example, poly(methyl methacrylate)], polyesters [for example, polyethylene terephthalate (PET)], polycarbonates, polyimides, polyamides, polyolefins (for example, polypropylene), polynorbornenes, cellulose compounds, polyvinyl alcohol (PVA), and polyvinylpyrrolidone.

Examples of the cellulose compound include hydroxypropylmethyl cellulose (HPMC), hydroxyethyl cellulose (HEC), methyl cellulose (MC), hydroxypropyl cellulose (HPC), and carboxymethyl cellulose (CMC).

In addition, the polymer material may be a conductive polymer material.

Examples of the conductive polymer material include polyaniline and polythiophene.

Examples of the inorganic material include silica, mullite, and alumina

In addition, as the binder, those described in paragraphs 0051 and 0052 of JP2014-212117A can also be used.

In a case where the metal-containing layer includes a binder, the metal-containing layer may include only one kind of the binder, or may include two or more kinds thereof.

In a case where the silver nanowire layer includes a binder, the content of the binder in the silver nanowire layer is preferably 1% by mass to 99% by mass and more preferably 5% by mass to 80% by mass with respect to a total mass of the silver nanowire layer.

The thickness of the metal-containing layer is not particularly limited, but from the viewpoint of transparency and conductivity, is preferably 1 nm to 400 nm and more preferably 10 nm to 200 nm. Within the above-described range, low resistance electrode can be formed relatively easily.

The thickness of the metal-containing layer is measured by the following method.

In a cross-sectional observation image of the metal-containing layer in a thickness direction, the arithmetic average value of the thickness of the metal-containing layer measured at five randomly selected points is obtained, and the obtained value is defined as the thickness of the metal-containing layer. The cross-sectional observation image of the metal-containing layer in the thickness direction can be obtained by using a scanning electron microscope (SEM).

In addition, the width of the metal-containing layer can also be measured in the same manner as the measuring method of the thickness of the metal-containing layer.

Specific Example of Photosensitive Transfer Material

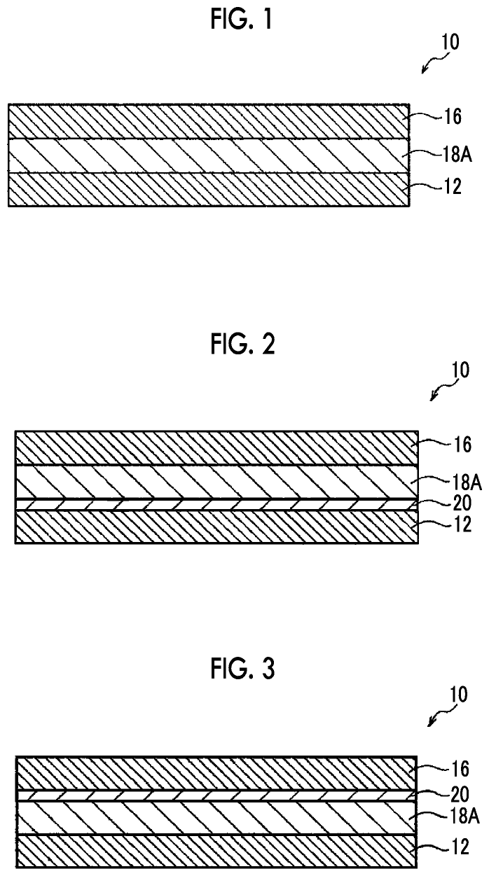

FIG. 1 is a schematic cross-sectional view showing a photosensitive transfer material 10 which is a specific example of the photosensitive transfer material according to the present disclosure. As shown in FIG. 1, the photosensitive transfer material 10 has a laminated structure of temporary support 12/photosensitive layer 18A/protective film 16 (that is, laminated structure in which a temporary support 12, a photosensitive layer 18A, and a protective film 16 are arranged in this order).

FIG. 2 is a schematic cross-sectional view showing a photosensitive transfer material 10 that is another specific example of the photosensitive transfer material according to the present disclosure. As shown in FIG. 2, the photosensitive transfer material 10 has a laminated structure of temporary support 12/antistatic layer 20/photosensitive layer 18A/protective film 16 (that is, laminated structure in which a temporary support 12, an antistatic layer 20, a photosensitive layer 18A, and a protective film 16 are arranged in this order).

Furthermore, FIG. 3 is a schematic cross-sectional view showing a photosensitive transfer material 10 that is the other specific example of the photosensitive transfer material according to the present disclosure. As shown in FIG. 3, the photosensitive transfer material 10 has a laminated structure of temporary support 12/photosensitive layer 18A/antistatic layer 20/protective film 16 (that is, laminated structure in which a temporary support 12, a photosensitive layer 18A, an antistatic layer 20, and a protective film 16 are arranged in this order).

However, the photosensitive transfer material according to the present disclosure is not limited to the photosensitive transfer material 10, and the protective film 16 may be omitted, for example.

Method of Producing Photosensitive Transfer Material

A method of producing a photosensitive transfer material is not particularly limited, but the photosensitive transfer material can be preferably produced by the following method of producing the photosensitive transfer material according to the present disclosure.

The method of producing a photosensitive transfer material according to the present disclosure includes

a step of preparing a temporary support, and

a step of forming the photosensitive layer on one side of the temporary support.

A method of forming the photosensitive layer is not particularly limited, and a known method can be used.

As an example of the method of forming the photosensitive layer, a method of forming the photosensitive layer by applying a photosensitive composition of an aspect including a solvent onto a temporary support and then drying, as necessary is used. The details of a component contained in the photosensitive composition are the same as those described above for the photosensitive layer, but regarding a content of the component, “with respect to a total mass of the photosensitive layer” is replaced to “with respect to a total solid content of the photosensitive composition”

As a coating method, a known method can be used.

Examples of the coating method include a printing method, a spray coating method, a roll coating method, a bar coating method, a curtain coating method, a spin coating method, and a die coating method (that is, a slit coating method).

Among these, a die coating method is preferable as the coating method.

As a drying method, known methods such as natural drying, heating drying, and drying under reduced pressure can be used, and these methods can be applied alone or in combination of plural thereof.

In the present disclosure, the “drying” means removing at least a part of the solvent included in the composition.

It is preferable to use a solvent for forming the photosensitive layer. In a case where the above-described photosensitive composition includes a solvent, the formation of the photosensitive layer by coating tends to be easier.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

As the solvent, a solvent described in paragraphs 0054 and 0055 of US2005/282073A can also be used, and the contents of the present specification are incorporated in the present disclosure.

In addition, as the solvent, an organic solvent (high boiling point solvent) having a boiling point of 180° C. to 250° C. can also be used, as necessary. In a case where a high boiling point solvent is contained, the content thereof is preferably 2% by mass to 20% by mass with respect to the total solvent.

In a case where the above-described photosensitive composition includes a solvent, the photosensitive composition may include only one kind of the solvent, or may include two or more kinds thereof.

The solid content of the above-described photosensitive composition is preferably 5% by mass to 80% by mass, more preferably 5% by mass to 40% by mass, and particularly preferably 5% by mass to 30% by mass with respect to a total mass of the photosensitive composition.

For example, from the viewpoint of coatability, the viscosity of the above-described photosensitive composition at 25° C. is preferably 1 mPa·s to 50 mPa·s, more preferably 2 mPa·s to 40 mPa·s, and still more preferably 3 mPa·s to 30 mPa·s.

The viscosity is measured using a viscometer. As the viscometer, for example, a viscometer (product name: VISCOMETER TV-22) manufactured by Toki Sangyo Co., Ltd. can be suitably used. However, the viscometer is not limited thereto.

For example, from the viewpoint of coatability, the surface tension of the above-described photosensitive composition at 25° C. is preferably 5 mN/m to 100 mN/m, more preferably 10 mN/m to 80 mN/m, and still more preferably 15 mN/m to 40 mN/m.

The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited thereto.

It is not necessary that the solvent used in forming the photosensitive layer is completely removed. For example, the content of the solvent in the photosensitive layer is preferably 5% by mass or less, more preferably 1% by mass or less, and particularly preferably 0.5% by mass or less with respect to a total mass of the photosensitive layer. From the viewpoint of imparting developability and the like, the content of the solvent in the photosensitive layer is preferably 0.05% by mass or more.

The method of producing the photosensitive transfer material may include a step of smodofying a surface on the one side of the temporary support between the step of preparing the temporary support and the step of forming the photosensitive layer.

For example, in order to improve the adhesiveness between the temporary support and the photosensitive layer, the side where the temporary support comes into contact with the photosensitive layer may be subjected to surface-modifying by ultraviolet (UV) irradiation, corona discharge, plasma, or the like.

In a case where the surface-modifying is carried out by the UV irradiation, the exposure amount is preferably 10 mJ/cm² to 2,000 mJ/cm², more preferably 50 mJ/cm² to 1,000 mJ/cm², still more preferably 50 mJ/cm² to 500 mJ/cm², and particularly preferably 50 mJ/cm² to 200 mJ/cm². By the exposure amount being within the above range, the adhesiveness between the photosensitive layer and the temporary support and peelability of the protective film are excellent.

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode (LED), all of which emit light in a wavelength range of 150 nm to 450 nm.

The irradiation amount of light is not particularly limited, and is preferably an amount within the above exposure amount range. The lamp output and the illuminance are not particularly limited.

The method of producing the photosensitive transfer material may include a step of volatilizing ammonia disclosed in a paragraph 0056 of WO2016/009980A, between the step of forming the photosensitive layer and the step of forming the protective film.

Film

The film according to the present disclosure includes a metal-containing layer, and a resin layer that contains a binder polymer and a compound A and that is disposed on a surface of the metal-containing layer, in which a number of hydrophilic groups in the compound A can be decreased by an action of light or heat.

In a case where the photosensitive transfer material according to the present disclosure is used to form the film according to the present disclosure, a film formed in such a manner that the photosensitive layer is transferred onto a metal-containing layer, a film formed in such a manner that the photosensitive layer is transferred onto a metal-containing layer and cured, a film formed in such a manner that the photosensitive layer is transferred onto a metal-containing layer, exposed to form a pattern, and cured, a film formed in such a manner that a photosensitive composition is applied onto a metal-containing layer, dried to form a photosensitive layer, exposed to form a pattern, and cured, and the like can be used.

In the film according to the present disclosure, the compound A can be transferred from the resin layer to the metal-containing layer through the storage (in some aspects, treatment of leaving it to stand).

The metal-containing layer is as described above for the photosensitive transfer material.

In addition, the shape of the above-described resin layer is not particularly limited, and may have a desired patterned shape.

Furthermore, the above-described resin layer may have an opening portion.

The opening portion can be formed by dissolving an unexposed portion of the photosensitive layer with a developer.

The above-described resin layer preferably includes a cured resin obtained by curing a curable component (the polymerizable compound, the photopolymerization initiator, the thermal crosslinking compound, and the like) in the above-described photosensitive layer by a reaction such as polymerization.

In addition, the preferred aspect of components other than the curable component in the above-described resin layer is the same as the preferred aspect in the above-described photosensitive layer, and the preferred content of these components in the above-described resin layer is also the same as in the preferred aspect in the above-described photosensitive layer.

In addition, the preferred thickness of the above-described resin layer is the same as the preferred thickness of the above-described photosensitive layer.

The compound A in the resin layer of the film has the same meaning as the compound A in the photosensitive layer of the photosensitive transfer material according to the embodiment in the present disclosure, and the preferred aspect is also the same.

A content of each component in the resin layer is the same as described above for the photosensitive layer. Regarding a content of the component, “with respect to a total mass of the photosensitive layer” is replaced to “with respect to a total solid content of the resin layer”.

The above-described resin layer is preferably a layer obtained by curing the photosensitive layer in the photosensitive transfer material according to the present disclosure.

The resin contained in the above-described resin layer is not particularly limited, and a known resin can be used.

Specific examples of the resin include an acrylic resin, a styrene resin, an epoxy resin, an amide resin, an amide epoxy resin, an alkyd resin, a phenol resin, an ester resin, a urethane resin, an epoxy acrylate resin obtained by the reaction of an epoxy resin and (meth)acrylic acid, an acid-modified epoxy acrylate resin obtained by the reaction of an epoxy acrylate resin and acid anhydride, and the like. These resins may be used alone or two or more kinds thereof may be used in combination.

Among these, a binder polymer used for the above-described photosensitive layer is suitably mentioned.

The above-described resin layer is preferably a layer obtained by curing the photosensitive layer, and more preferably a layer formed by curing the photosensitive layer with any patterned shape.

The thickness of the above-described resin layer is not particularly limited and can be appropriately selected as desired, but for example, the thickness is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

From the viewpoint of the migration resistance, a content of chloride ions included in the above-described resin layer is preferably 50 ppm or less, more preferably 20 ppm or less, still more preferably 10 ppm or less, particularly preferably 5 ppm or less, and most preferably 1 ppm or less with respect to a total mass of the resin layer.

The resin layer may contain components (other components) other than the polymerizable compound, the photopolymerization initiator, the compound A, the hygroscopic material, and the resin (in some aspects, the binder polymer described above in the photosensitive layer).

As another component, a known additive can be used. Examples of another component suitably include components contained in the above-described photosensitive layer.

The resin layer is preferably achromatic. Specifically, in CIE1976 (L*, a*, b*) color space, the total reflection (incidence angle: 8°, light source: D-65 (visual field: 2°)) preferably has a resin layer L* value of 10 to 90, preferably has a resin layer a* value of −1.0 to 1.0, and preferably has a resin layer b* value of −1.0 to 1.0.

From the viewpoint of a rust inhibition property, a moisture permeability of the resin layer at a film thickness of 40 μm is preferably 500 g/(m²·24 hr) or less, more preferably 300 g/(m²·24 hr) or less, and still more preferably 100 g/(m²·24 hr) or less.

A method of producing a film according to the present disclosure will be described later in a method of producing a laminate, which is an embodiment including a substrate.

Capacitive Input Device

The capacitive input device according to the present disclosure includes the film according to the present disclosure and is preferably manufactured by using the photosensitive transfer material according to the present disclosure.

In addition, the above-described capacitive input device is preferably a touch panel. That is, the touch panel according to the present disclosure preferably includes the film according to the present disclosure.

In addition, the capacitive input device according to the present disclosure is preferably a laminate in which a substrate, an electrode that is the above-described metal-containing layer, and the above-described resin layer are laminated in this order. In this case, the above-described electrode and the above-described resin layer correspond to the film according to the present disclosure.

The substrate is the same as that described later for a method of producing a laminate.

The preferred aspect of the electrode as the above-described metal-containing layer in the capacitive input device according to the present disclosure is the same as the preferred aspect of the above-described metal-containing layer in the film according to the present disclosure.

The above-described electrode may be a transparent electrode pattern or a lead wire. The above-described electrode is preferably an electrode pattern and more preferably a transparent electrode pattern.

As the transparent electrode pattern, a layer containing metal fibers or a metal mesh layer is preferable, a layer containing metal fibers is more preferable, and the silver nanowire layer described above is particularly preferable.

As a material of the lead wire, metal is preferable. Examples of the metal which is the material of the lead wire include gold, silver, copper, molybdenum, aluminum, titanium, chromium, zinc, and manganese, and alloy consisting of two or more kinds of these metal elements. As the material of the lead wire, copper, molybdenum, aluminum, or titanium is preferable, copper is particularly preferable.

The preferred aspect of the above-described resin layer in the capacitive input device according to the present disclosure is the same as the preferred aspect of the above-described resin layer in the film according to the present disclosure.

In addition, the above-described resin layer in the capacitive input device according to the present disclosure may have a desired patterned shape.

The capacitive input device according to the present disclosure, preferably the touch panel according to the present disclosure, may include a refractive index adjusting layer.

The preferred aspect of the refractive index adjusting layer is the same as the preferred aspect of the refractive index adjusting layer which can be included in the photosensitive transfer material.

The refractive index adjusting layer may be formed by applying and drying a composition for forming the refractive index adjusting layer, or may be formed by transferring the refractive index adjusting layer of the photosensitive transfer material having the refractive index adjusting layer.

The aspect in which the touch panel includes the refractive index adjusting layer has an advantage in which the metal conductive material and the like are hardly visible (that is, wire visibility is suppressed).

It is preferable that the capacitive input device according to the present disclosure includes the substrate, the transparent electrode pattern that is the above-described metal, the above-described resin layer disposed adjacent to the transparent electrode pattern, and the refractive index adjusting layer disposed adjacent to the above-described resin layer, and a refractive index of the resin layer is higher than a refractive index of the refractive index adjusting layer. The refractive index of the above-described resin layer is preferably 1.6 or more.

In a case of adopting the above-described configuration, a covering property of the transparent electrode pattern is improved.

As the wire for a touch panel, for example, the lead wire (lead-out wire) disposed on the frame portion of the touch panel is used. As a material of the wire for a touch panel, metal is preferable. Examples of a metal which is the material of the wire for a touch panel include gold, silver, copper, molybdenum, aluminum, titanium, chromium, zinc, manganese, and alloy consisting of two or more kinds of these metal elements. Among these, as the metal which is the material of the wire for a touch panel, copper, molybdenum, aluminum, or titanium is preferable, and from the viewpoint of low electric resistance, copper is more preferable. On the other hand, since copper is easily oxidized and discolored, an antioxidant treatment may be applied to form a protective film (metal conductive material protective film).

With regard to the structure of the touch panel, a structure of a capacitive input device described in JP2014-10814A and JP2014-108541A may be referred to.

Preferred aspects of the laminate, pattern exposure, and development include the preferred aspects thereof in the method of producing a laminate described below.

The touch panel according to the present disclosure may include an ultraviolet (UV) ray absorbing layer having absorption at a wavelength range of 300 nm to 400 nm in the layer structure thereof. In a case where the UV absorbing layer is provided, it is desirable that the UV absorbing layer is disposed on the visual side of the photosensitive layer. The UV absorbing layer can protect the photosensitive layer from sunlight and suppress the excitation and decomposition of the compound A.

In the UV absorbing layer, the sum of absorbances at a wavelength of 300 nm to 400 nm is preferably 10 or more and 500 or less, more preferably 150 or more and 500 or less, and still more preferably 300 or more and 500 or less. By setting the sum of the absorbances within the above-described range, decomposition of the compound A can be suppressed while maintaining the transparency.

As the UV absorbing layer, an OCA to which a polarizing element and a UV absorber are added, a protective film, soda glass, or the like can be used.

Specific Example of Touch Panel

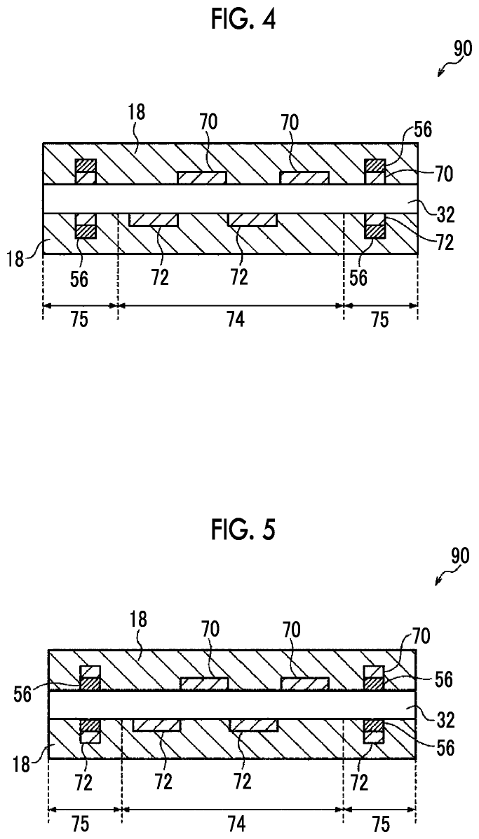

FIG. 4 is a schematic cross-sectional view of a touch panel 90 which is a first specific example of the touch panel according to the present disclosure.

As shown in FIG. 4, the touch panel 90 has an image display region 74 and an image non-display region 75 (that is, frame portion).

In addition, the touch panel 90 includes the electrode for a touch panel on both surfaces of the substrate 32. Specifically, the touch panel 90 includes a first metal conductive material 70 on one surface of the substrate 32 and includes a second metal conductive material 72 on the other surface thereof.

In the touch panel 90, a lead wire 56 is connected to the first metal conductive material 70 and the second metal conductive material 72, respectively. The lead wire 56 is, for example, a copper wire or a silver wire.

In the touch panel 90, a metal conductive material protective film 18 is formed on one surface of the substrate 32 so as to cover the first transparent electrode pattern 70 and the lead wire 56, and the metal conductive material protective film 18 is formed on the other surface of the substrate 32 so as to cover the second metal conductive material 72 and the lead wire 56.

The refractive index adjusting layer may be formed on one surface of the substrate 32.

In addition, FIG. 5 is a schematic cross-sectional view of the touch panel 90 which is the second specific example of the touch panel according to the present disclosure.

As shown in FIG. 5, the touch panel 90 has the image display region 74 and the image non-display region 75 (that is, frame portion).

In addition, the touch panel 90 includes the electrode for a touch panel on both surfaces of the substrate 32. Specifically, the touch panel 90 includes a first metal conductive material 70 on one surface of the substrate 32 and includes a second metal conductive material 72 on the other surface thereof.

In the touch panel 90, a lead wire 56 is connected to the first metal conductive material 70 and the second metal conductive material 72, respectively. The lead wire 56 is, for example, a copper wire or a silver wire. In addition, the lead wire 56 is formed inside surrounded by the metal conductive material protective film 18, and the first metal conductive material 70 or the second metal conductive material 72.

In the touch panel 90, a metal conductive material protective film 18 is formed on one surface of the substrate 32 so as to cover the first transparent electrode pattern 70 and the lead wire 56, and the metal conductive material protective film 18 is formed on the other surface of the substrate 32 so as to cover the second metal conductive material 72 and the lead wire 56.

The refractive index adjusting layer may be formed on one surface of the substrate 32.

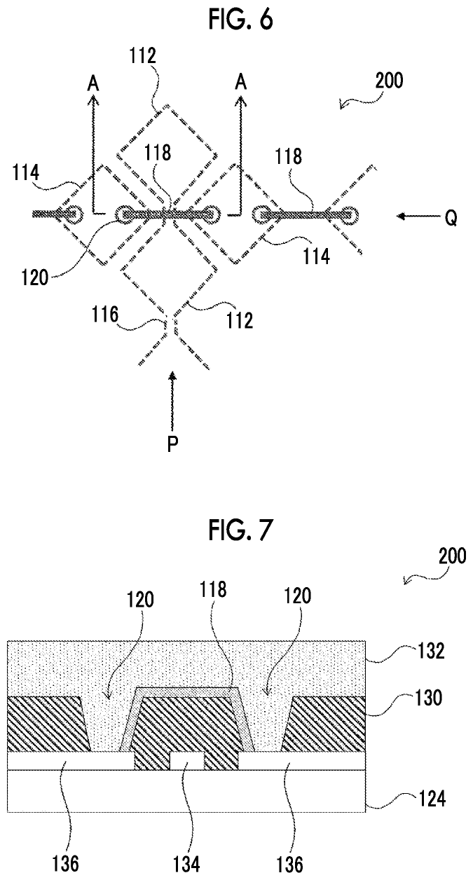

Still another embodiment of the touch sensor of the present disclosure will be described with reference to FIGS. 6 and 7.

FIG. 6 is a schematic plane view showing still another specific example of the touch panel according to the present disclosure, and FIG. 7 is a cross-sectional view taken along line A-A of FIG. 6.

FIGS. 6 and 7 show a transparent laminate 200 including a transparent electrode pattern (including a first island-shaped electrode portion, a first wiring portion 116, a second island-shaped electrode portion, and a bridge wiring 118), a protective layer 130, and an overcoat layer 132 on a transparent film substrate 124, in this order.

It is preferable that the protective layer 130 and the overcoat layer 132 are layers formed of the film according to the present disclosure or formed by curing the film according to the present disclosure.

As shown in FIGS. 6 and 7, through-holes 120 for connecting a second island-shaped electrode portion 114 and the bridge wiring (a second wiring portion) 118 to make a bridge between two adjacent second island-shaped electrode portions 114 and to electrically connect the second island-shaped electrode portions 114 to each other are formed on the protective layer 130 positioned on the second island-shaped electrode portion 114 in the transparent electrode pattern on the transparent film substrate 124.

The touch sensor 200 has a first electrode pattern 134 and a second electrode pattern 136 extending in a direction of an arrow P or a direction of an arrow Q, which intersect with each other, on the transparent substrate 124, respectively.

FIGS. 6 and 7 show only a part of the touch sensor, but on the transparent substrate, the first electrode pattern 134 is arranged in one direction (first direction) over a wide range of the transparent substrate, and furthermore, the second electrode pattern 136 is arranged in a direction (second direction) different from the first direction over a wide range of the transparent substrate.

In FIG. 6, in the first electrode pattern 134, a plurality of square electrode portions (first island-shaped electrode portions) 112 are arranged in an island shape at equal intervals along the direction of the arrow P on the transparent substrate 124, and the first island-shaped electrode portions 112 adjacent to each other are connected through the first wiring portion 116 in a row. As a result, a long electrode is formed in one direction on a surface of the transparent substrate.

The first wiring portion is preferably formed of the same material as the first island-shaped electrode portion.

In FIG. 6, in the second electrode pattern 136, square electrode portions (second island-shaped electrode portions) 114 substantially similar to the first island-shaped electrode portions are arranged in an island shape at equal intervals along the direction of the arrow Q, which is substantially orthogonal to the direction of the arrow P, on the transparent substrate 124, and the second island-shaped electrode portions 114 adjacent to each other are connected through the second wiring portion 118 (bridge wiring) in a row.

As a result, a long electrode is formed in one direction different from the first electrode pattern on the surface of the transparent substrate.

As shown in FIGS. 6 and 7, the first electrode pattern 134 and the second electrode pattern 136 are provided with a bridge structure in which one of the intersecting electrodes jumps over the other at an intersecting portion so as not to conduct with each other.

In the touch sensor shown in FIG. 7, the protective layer 130 is arranged and installed to cover the first electrode pattern 134 and the second electrode pattern 136.

Laminate

The laminate according to the present disclosure includes a substrate that includes a metal-containing layer on a surface, and a resin layer that contains a binder polymer and a compound A and that is disposed on a surface of the metal-containing layer, in which a number of hydrophilic groups in the compound A can be decreased by an action of light or heat. The laminate may include a UV absorbing layer.

Preferred aspects of the substrate, the UV absorbing layer, and the like in the laminate according to the present disclosure are the same as the preferred aspect of the substrate, the UV absorbing layer, and the like described above.

The resin layer in the laminate according to the present disclosure is a layer formed by curing the above-described photosensitive layer or a layer formed by the above-described photosensitive layer on which a pattern is formed and cured as necessary, and is preferably a layer formed by curing the photosensitive layer in a patterned manner.

A preferred aspect of the resin layer in the laminate according to the present disclosure is the same as the above-described photosensitive layer or a layer cured in a patterned manner.

Other elements in the laminate according to the present disclosure can also be provided with reference to the above-described touch panel and the like.

Method of Producing Laminate

A method of producing a laminate according to the present disclosure is not particularly limited as long as the method is a method using the photosensitive composition or the photosensitive transfer material according to the present disclosure, and for example, the following method of producing a laminate according to the present disclosure is suitably used.

In another aspect, the method of producing a laminate according to the present disclosure includes a step of transferring at least the photosensitive layer in the photosensitive transfer material according to the present disclosure to a substrate including a metal-containing layer on a surface (referred to as the “photosensitive layer forming step”), a step of performing pattern exposure on the photosensitive layer (referred to as the “pattern exposure step”), and a step of developing the photosensitive layer and forming a pattern (referred to as the “development step”), in this order.

Hereinafter, each step according to the present disclosure will be described.

Photosensitive Layer Forming Step

The photosensitive layer forming step is a step of transferring at least the photosensitive layer of the photosensitive transfer material according to the present disclosure to a substrate including a metal-containing layer on a surface.

In the photosensitive layer forming step, the photosensitive layer is formed by laminating the photosensitive transfer material according to the present disclosure on a surface on which a metal-containing layer is disposed, in the substrate with the surface on which the metal-containing layer is disposed, and by transferring the photosensitive layer of the photosensitive transfer material according to the present disclosure to the surface.

The laminating (so-called transfer of the photosensitive layer) can be performed using a known laminator such as a vacuum laminator or an auto-cut laminator.

As the laminating condition, a general condition can be applied.

The laminating temperature is preferably 80° C. to 150° C., more preferably 90° C. to 150° C., and still more preferably 100° C. to 150° C.

In a case of using a laminator including a rubber roller, the laminating temperature indicates a temperature of the rubber roller.

A temperature of the substrate in a case of laminating is not particularly limited.

The temperature of the substrate in a case of laminating is preferably 10° C. to 150° C., more preferably 20° C. to 150° C., and still more preferably 30° C. to 150° C.

In a case of using a resin substrate as the substrate, the temperature of the substrate in a case of laminating is preferably 10° C. to 80° C., more preferably 20° C. to 60° C., and still more preferably 30° C. to 50° C.

In addition, the linear pressure in a case of laminating is preferably 0.5 N/cm to 20 N/cm, more preferably 1 N/cm to 10 N/cm, and still more preferably 1 N/cm to 5 N/cm.

In addition, the transportation speed (laminating speed) in a case of laminating is preferably 0.5 m/min to 5 m/min and more preferably 1.5 m/min to 3 m/min.

In a case of using the photosensitive transfer material having a laminated structure of protective film/photosensitive layer/interlayer/thermoplastic resin layer/temporary support, first, the protective film is peeled off from the photosensitive transfer material to expose the photosensitive layer, the photosensitive transfer material and the substrate are attached to each other so that the exposed photosensitive layer and the surface on which the metal-containing layer is disposed are in contact with each other, and heating and pressurizing are performed. By such an operation, the photosensitive layer of the photosensitive transfer material is transferred onto the surface on which the metal-containing layer is disposed, and a film having a laminated structure of temporary support/thermoplastic resin layer/interlayer/photosensitive layer/metal-containing layer/substrate is formed. In this laminated structure, the portion of the “metal-containing layer/substrate” is the substrate including a metal-containing layer on the surface.

Thereafter, the temporary support is peeled off from the laminate having the laminated structure, as necessary. However, the pattern exposure which will be described later can be also performed, by leaving the temporary support.

As an example of the method of transferring the photosensitive layer of the photosensitive transfer material on the substrate and performing pattern exposure and development, a description disclosed in paragraphs 0035 to 0051 of JP2006-23696A can also be referred to.

Examples of the substrate used in the method of producing a laminate according to the present disclosure include substrates formed of various materials including a metal-containing layer on a surface, for example, a resin substrate, a glass substrate, a metal substrate, a silicon substrate, and the like, and a known structure such as an electrode may be further provided on a surface of the substrate and inside the substrate.

Among these, a glass substrate or a resin substrate is preferable as the above-described substrate.

In addition, the substrate is preferably a transparent substrate and more preferably a transparent resin substrate. The transparency in the present disclosure means that the transmittance of all visible light is 85% or more, preferably 90% or more, and more preferably 95% or more.

A refractive index of the substrate is preferably 1.50 to 1.52.

As the glass substrate, tempered glass such as GORILLA GLASS (registered trademark) manufactured by Corning Incorporated can be used. The thickness of the glass substrate is preferably 0.01 mm or more and 1.1 mm or less, and more preferably 0.1 mm or more and 0.7 mm or less.

As the resin substrate, at least one of a substrate with no optical strains or a substrate having high transparency is preferably used, and examples thereof include a substrate consisting of a resin such as polyethylene terephthalate (PET), polyethylene naphthalate (PEN), polycarbonate (PC), triacetyl cellulose (TAC), polyimide (PI), polybenzoxazole (PBO), and cycloolefin polymer (COP). From the viewpoint of strength and flexibility, the thickness of the resin substrate is preferably 1.0 μm or more and 100 μm or less, and more preferably 5.0 μm or more and 50 μm or less.

As a material of the transparent substrate, a material disclosed in JP2010-86684A, JP2010-152809A, and JP2010-257492A is preferably used.

The metal-containing layer is as described above for the photosensitive transfer material.

Pattern Exposure Step

The pattern exposure step is a step of performing a pattern exposure of the above-described photosensitive layer after the above-described photosensitive layer forming step.

The “pattern exposure” refers to exposure of the aspect of performing the exposure in a patterned shape, that is, the aspect in which an exposed portion and an unexposed portion are present.

For example, in a case where the photosensitive layer is a negative type, the exposed portion of the photosensitive layer on the substrate in the pattern exposure is cured and finally becomes the cured film. Meanwhile, the unexposed portion of the photosensitive layer on the substrate in the pattern exposure is not cured, and is dissolved and removed with a developer in the subsequent development step. With the unexposed portion, the opening portion of the cured film can be formed after the development step.

The pattern exposure may be an exposure through a mask or may be a digital exposure using a laser or the like.

In a case where it is not necessary to pattern the photosensitive layer, the laminate can be produced by, for example, a step of exposing the entire surface of the photosensitive layer instead of the pattern exposure step.

As a light source of the pattern exposure, a light source can be appropriately selected, as long as it can emit light at a wavelength range (for example, 365 nm or 405 nm) at which the photosensitive layer can be cured.

Examples of the light source include various lasers, a light emitting diode (LED), an ultra-high pressure mercury lamp, a high pressure mercury lamp, and a metal halide lamp.

The exposure amount is preferably 5 mJ/cm² to 200 mJ/cm² and more preferably 10 mJ/cm² to 200 mJ/cm².

In a case where the photosensitive layer is formed on the substrate using the photosensitive transfer material, the pattern exposure may be performed after peeling the temporary support, or the temporary support may be peeled off after performing the pattern exposure before peeling off the temporary support.

In addition, in the exposure step, the heat treatment (so-called post exposure bake (PEB)) may be performed with respect to the photosensitive layer after the pattern exposure and before the development.

Development Step

The development step is a step of developing the above-described photosensitive layer after the above-described pattern exposure step (that is, by dissolving the unexposed portion in the pattern exposure in a developer) to form a pattern.

A developer used in the development is not particularly limited, and a well-known developer such as a developer disclosed in JP1993-72724A (JP-H05-72724A) can be used.

As the developer, an alkali aqueous solution is preferably used.

Examples of an alkali compound which can be included in the alkali aqueous solution include sodium hydroxide, potassium hydroxide, sodium carbonate, potassium carbonate, sodium hydrogen carbonate, potassium hydrogen carbonate, tetramethyl ammonium hydroxide, tetraethyl ammonium hydroxide, tetrapropyl ammonium hydroxide, tetrabutyl ammonium hydroxide, and choline (2-hydroxyethyltrimethyl ammonium hydroxide).

The pH of the alkali aqueous solution at 25° C. is preferably 8 to 13, more preferably 9 to 12, and particularly preferably 10 to 12.

The content of the alkali compound in the alkali aqueous solution is preferably 0.1% by mass to 5% by mass and more preferably 0.1% by mass to 3% by mass with respect to a total mass of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

The concentration of the organic solvent is preferably 0.1% by mass to 30% by mass.

The developer may include a known surfactant.

The concentration of the surfactant is preferably 0.01% by mass to 10% by mass.

The liquid temperature of the developer is preferably 20° C. to 40° C.

Examples of the development method include methods such as puddle development, shower development, shower and spin development, and dip development.

In a case of the shower development, an uncured portion of the photosensitive layer is removed by the developer being sprayed to the photosensitive layer after the pattern exposure as a shower.

In a case of using the photosensitive transfer material including the photosensitive layer and at least one of the thermoplastic resin layer or the interlayer, after the transfer of these layers onto the substrate and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance, or the thermoplastic resin layer and the interlayer may be removed while the uncured portion is removed.

In addition, after the development, the development residue is preferably removed by spraying a washing agent with a shower and rubbing with a brush or the like.

The liquid temperature of the developer is preferably 20° C. to 40° C.

The development step may include a stage of performing the development, and a stage of performing the heat treatment (hereinafter, also referred to as “post baking”) with respect to the cured film obtained by the development. The method of producing a laminate according to the present disclosure may include a step of heating the photosensitive layer after the step of forming a pattern. It may make easy to enhance migration resistance in the aspect in which a number of hydrophilic groups in the compound A decreases by action of heat.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In a case where the photosensitive layer includes a carboxy group-containing (meth)acrylic resin, at least a part of the carboxy group-containing (meth)acrylic resin can be changed to carboxylic acid anhydride by the post baking. In a case of being changed in this way, developability and hardness of the cured film are excellent.

The development step may include a stage of performing the development, and a stage of exposing the cured film obtained by the development (hereinafter, also referred to as “post exposure”).

In a case where the development step includes both a stage of performing the post exposure and a stage of performing the post baking, it is preferable to perform the post baking after the post exposure.

With regard to the pattern exposure and the development, for example, a description described in paragraphs 0035 to 0051 of JP2006-23696A can be referred to.

The method of producing a laminate according to the present disclosure may further include an additional step (so-called another step) in addition to the steps described above.

Examples of such another step include a known step (for example, washing step) which may be provided in a normal photolithography step.

Method of Suppressing Deterioration

The method of suppressing deterioration according to the present disclosure is a method of suppressing deterioration of a metal in a film that includes a metal-containing layer and a resin layer that is disposed on a surface of the metal-containing layer and that contains a binder polymer, in which the resin layer contains a compound A, and a number of hydrophilic groups in the compound A can be decreased by an action of light or heat.

In a case where the photosensitive transfer material according to the present disclosure is used to form the above-described film, a film formed in such a manner that the photosensitive layer is transferred onto a metal-containing layer, a film formed in such a manner that the photosensitive layer is transferred onto a metal-containing layer and cured, a film formed in such a manner that the photosensitive layer is transferred onto a metal-containing layer, exposed to form a pattern, and cured, and the like can be used.

The compound A in the resin layer of the film has the same meaning as the compound A in the photosensitive layer of the photosensitive transfer material according to the embodiment in the present disclosure, and the preferred aspect is also the same.

The content of the compound A in the resin layer is the same as described above for the photosensitive layer, but regarding a content of the component, “with respect to a total mass of the photosensitive layer” is replaced to “with respect to a total solid content of the resin layer”.

As the film including the metal-containing layer and the resin layer in the method of suppressing deterioration according to the present disclosure, the film according to the present disclosure is suitably mentioned.

In the method of suppressing deterioration according to the present disclosure, it is preferable to use the photosensitive transfer material according to the present disclosure.

In a case where the photosensitive transfer material according to the present disclosure is used to form the above-described film, a film formed in such a manner that the photosensitive layer is transferred onto a metal-containing layer, a film formed in such a manner that the photosensitive layer is transferred onto a metal-containing layer and cured, a film formed in such a manner that the photosensitive layer is transferred onto a metal-containing layer, exposed to form a pattern, and cured, and the like can be used.

The metal-containing layer in the method of suppressing deterioration according to the present disclosure has the same meaning as the metal-containing layer in the film in the present disclosure, and the preferred aspect is also the same.

The resin contained in the above-described resin layer is not particularly limited, and a known resin can be used.

Specific examples of the resin include those described above as the resin contained in the resin layer of the film according to the present disclosure.

Among these, a binder polymer used for the above-described photosensitive layer is suitably mentioned.

The above-described resin layer is preferably the above-described photosensitive layer or a layer obtained by curing the above-described photosensitive layer, and more preferably the above-described photosensitive layer or a layer formed by curing the photosensitive layer with any pattern shape.

The thickness of the above-described resin layer is not particularly limited and can be appropriately selected as desired, but for example, the thickness is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

From the viewpoint of the migration resistance, a content of chloride ions included in the above-described resin layer is preferably 50 ppm or less, more preferably 20 ppm or less, still more preferably 10 ppm or less, particularly preferably 5 ppm or less, and most preferably 1 ppm or less with respect to a total mass of the resin layer.

The resin layer may contain components (other components) other than the polymerizable compound, the photopolymerization initiator, the compound A and the resin (in some aspects, the binder polymer described above in the photosensitive layer).

As another component, a known additive can be used. Examples of another component suitably include components contained in the above-described photosensitive layer.

The method of suppressing deterioration according to the present disclosure may include a step of transferring at least the above-described photosensitive layer in the photosensitive transfer material according to the present disclosure to a substrate including a metal-containing layer on a surface, a step of performing a pattern exposure on the above-described photosensitive layer, and a step of developing the above-described photosensitive layer to form a pattern, in this order.

Each step described above is the same as each step in the method of producing a laminate according to the present disclosure.

In the method of suppressing deterioration according to the present disclosure, in a case where the film is a film including the resin layer on a metal-containing layer, the step of removing the resin layer may be provided after the compound A adheres to a surface of the metal-containing layer or after the compound A is diffused into the above-described layer containing a metal.

The method of suppressing deterioration according to the present disclosure may include an additional step (so-called another step) in addition to the steps described above.

Examples of such another step include the another step in the method of producing a laminate according to the present disclosure, and any another known step.

### EXAMPLES

Hereinafter, the present disclosure will be described in more detail with reference to Examples.

The material, the amount used, the ratio, the process contents, the process procedure, and the like shown in the following examples can be appropriately changed, within a scope not departing from a gist of the present disclosure. Accordingly, the scope of the present disclosure is not limited to specific examples shown below.

Preparation of Photosensitive Composition

Photosensitive compositions A-1 to A-7 were prepared according to the description in Table 1 below. The numerical values in individual component columns in Table 1 represent the mass ratio.

Details of the abbreviations shown in Table 1 are shown below.

Binder Polymer

Compound P-1: Polymer having a structure shown below, weight-average molecular weight of 17000, the following numerical value indicates a compositional ratio (molar ratio).

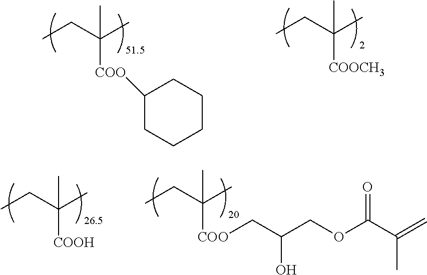

Compound P-2: Polymer having a structure shown below, weight-average molecular weight of 17000, the following numerical value indicates a compositional ratio (mass ratio).

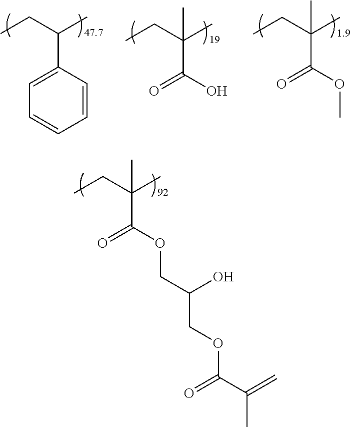

Compound P-3: Random copolymerized substance of benzyl methacrylate/methacrylic acid=72/28 (molar ratio), weight-average molecular weight: 37000

A P-1 solution (solid content of 27% by mass solution of a polymer P-1) was prepared as follows.

Styrene (38.4 g), methacrylic acid (34.0 g), dicyclopentanyl methacrylate (30.1 g), V-601 (trade name; manufactured by FUJIFILM Wako Pure Chemical Corporation, 5.4 g) as a polymerization initiator, and propylene glycol monomethyl ether (63.6 g) were added to and mixed with propylene glycol monomethyl ether (82.4 g) heated to 90° C. under a nitrogen stream to obtain a solution, and the solution was added dropwise for 3 hours. Next, after a reaction was carried out at 90° C. for 1 hour, 0.75 g of V-601 was added 3 times every 1 hour. Next, a reaction was carried out at 90° C. for another 3 hours to obtain a reaction solution, and the obtained reaction solution was then diluted with propylene glycol monomethyl ether acetate (58.4 g) and propylene glycol monomethyl ether (11.7 g), thereby obtaining a polymer solution. Glycidyl methacrylate (trade name: Blemmer GH, manufactured by NOF CORPORATION, 25.5 g), which is a polymerizable compound having a cyclic ether group, tetrabutylammonium acetate (manufactured by Tokyo Chemical Industry Co., Ltd., 1.14 g) which is an ammonium carboxylate, as a catalyst, and p-methoxyphenol (0.26 g) were added to and mixed with the obtained polymer solution, and were reacted with each other at 100° C. for 7 hours under an air stream, thereby obtaining a solution containing a polymer (P-1). Propylene glycol monomethyl ether acetate was added to the obtained solution containing the polymer (P-1) to obtain a P-1 solution having a concentration of solid contents of 27% by mass. The residual amount of glycidyl methacrylate in the P-1 solution was measured by gas chromatography (GC) and found to be 0.1% by mass or less. A weight-average molecular weight of the obtained polymer was 17,000, and a dispersity was 2.1. The dispersity was measured by GPC in the same manner as the weight-average molecular weight. An acid value of the polymer determined by the following Expression X was 94.5 mgKOH/g.

Acid value of polymer=(acid value of solution)/(concentration of solid contents) Expression X

A P-2 solution (solid content of 36.3% by mass solution of a polymer P-2) was prepared as follows.

A solution (so-called monomer solution) obtained by dissolving styrene (172 g), methyl methacrylate (4.7 g), and methacrylic acid (112.1 g) in propylene glycol monomethyl ether (30 g) and a solution (so-called polymerization initiator solution) obtained by dissolving V-601 (manufactured by FUJIFILM Wako Pure Chemical Corporation, 27.6 g), which is an polymerization initiator, in propylene glycol monomethyl ether (57.7 g) were added dropwise to a solution of propylene glycol monomethyl ether (113.5 g) heated to 90° C. under a nitrogen stream for 3 hours by using separate dropwise addition pumps. After the dropwise addition, 2.5 g of V-601 was added three times every hour. Next, after a reaction was carried out at 90° C. for another 3 hours, the obtained reaction solution was then diluted with propylene glycol monomethyl ether acetate (160.7 g) and propylene glycol monomethyl ether (233.3 g), thereby obtaining a polymer solution. A temperature of the polymer solution was increased to 100° C. under an air stream. Tetrabutylammonium bromide acetate (5.2 g) which is an ammonium carboxylate, as a catalyst, and p-methoxyphenol (0.86 g) were added to this polymer solution, and glycidyl methacrylate (trade name: Blemmer GH, manufactured by NOF CORPORATION, 71.9 g), which is a polymerizable compound having a cyclic ether group was added dropwise thereto for 20 minutes, thereby carrying out a reaction at 100° C. for 7 hours to obtain a solution containing a polymer (P-2). Propylene glycol monomethyl ether acetate was added to the obtained solution containing the polymer (P-2) to obtain a P-2 solution having a concentration of solid contents of 27% by mass. In a case where the amount of a monomer remaining in the P-2 solution (so-called residual monomer) was measured by gas chromatography (GC), and was found that each monomer was 0.1% by mass or less with respect to a total solid content mass of the polymer solution. A weight-average molecular weight of the obtained polymer was 17,000, and a dispersity was 2.4. The dispersity was measured by GPC in the same manner as the weight-average molecular weight. An acid value of the polymer determined by the above Expression X was 124 mgKOH/g.

TABLE 1

| | | Photosensitive composition | | | | | | |
|---|---|---|---|---|---|---|---|---|
| | | (component amount: parts by mass) | | | | | | |
| Component | | A-1 | A-2 | A-3 | A-4 | A-5 | A-6 | A-7 |
| Polymerizable | Tricyclodecane dimethanol diacrylate (A-DCP, | | | | | | 2.00 | 2.00 |
| compound | manufactured by Shin-Nakamura Chemical | | | | | | | |
| | Co., Ltd.) | | | | | | | |
| | (A-NOD-N, manufactured by Shin-Nakamura | 6.08 | 6.08 | 6.08 | 6.08 | 6.08 | 6.08 | 6.95 |
| | Chemical Co., Ltd.) | | | | | | | |
| | 1,9-nonanediol diacrylate | | | | | | | |
| | (A-DPH, manufactured by Shin-Nakamura | 1.00 | 1.00 | 1.00 | 1.00 | 1.00 | 1.00 | 2.00 |
| | Chemical Co., Ltd.) dipentaerythritol hexaacrylate | | | | | | | |
| Binder polymer | P-1 solution (solid contents of 27% by mass, | | | | | | 37.44 | |
| | acid value: 94.5 mgKOH/g, Mw: 17,000, | | | | | | | |
| | dispersity Mw/Mn: 2.4) | | | | | | | |
| | P-2 solution (solid contents of 36.3% by mass, | | | | | 37.44 | | |
| | acid value: 124 mgKOH/g, Mw: 17,000, | | | | | | | |
| | dispersity Mw/Mn: 2.4) | | | | | | | |
| | Random copolymerized substance of benzyl | 10.11 | 10.11 | 10.11 | 10.11 | | | 12.64 |
| | methacrylate/methacrylic acid = 72/28 (molar ratio), | | | | | | | |
| | weight-average molecular weight: 37,000 | | | | | | | |
| Photoradical | 1-[9-Ethyl-6-(2-methylbenzoyl)-9H-carbazol-3-yl] | | | | | | 0.10 | |
| polymerization | ethanone-1-(O-acetyloxime) (OXE-02, | | | | | | | |
| initiator | manufactured by BASF SE) | | | | | | | |
| | 1-(Biphenyl-4-yl)-2-methyl-2-morpholinopropan- | 0.37 | 0.37 | 0.37 | 0.37 | | 0.27 | 0.47 |
| | 1-one (APi-307, manufactured by Shenzhen | | | | | | | |
| | UV-ChemTech Ltd.) | | | | | | | |
| | 2-(Dimethylamino)-2-[(4-methylphenyl)methyl]- | | | | | 0.30 | | |
| | 1-[4-(4-morpholinyl)phenyl]-1-butanone | | | | | | | |
| | (IRGACURE 379EG, manufactured by BASF SE) | | | | | | | |
| Compound A | AOI-SM (manufactured by SHOWA DENKO K.K.) | 4.40 | | | | | 4.40 | |
| causing | blocked isocyanate compound | | | | | | | |
| decrease in | Celoxide 2021P (manufactured by Daicel | | 4.40 | | | | | |
| hydrophilic | Corporation) epoxy compound | | | | | | | |
| group | ARONE OXETANE OXT-221 (manufactured by | | | 4.40 | | | | |
| | Toagosei Co., Ltd.) | | | | | | | |
| | Oxetane compound | | | | | | | |
| | Triethylene glycol divinyl ether (manufactured by | | | | 4.40 | | | |
| | Tokyo Chemical Industry Co., Ltd.) | | | | | | | |
| | vinyl ether compound | | | | | | | |
| | 1-Methyl-isoquinoline (manufactured by Tokyo | | | | | 4.40 | | |
| | Chemical Industry Co., Ltd.) | | | | | | | |
| | nitrogen-containing aromatic compound | | | | | | | |
| Photo-acid | CPI-200K (SANYO CHEMICAL INDUSTRIES, | | 0.02 | 0.02 | 0.02 | | | |
| generator | LTD.) | | | | | | | |
| Additive | 2-Naphthalenethiol (manufactured by Tokyo | 0.01 | 0.01 | 0.01 | 0.01 | 0.01 | 0.01 | 0.01 |
| | Chemical Industry Co., Ltd.) | | | | | | | |
| | 1,2,4-Triazole (manufactured by Otsuka | | | | | | 0.02 | |
| | Chemical Co., Ltd.) | | | | | | | |
| | FTERGENT 710FL (manufactured by NEOS | 0.07 | 0.07 | 0.07 | 0.07 | 0.07 | 0.07 | 0.07 |
| | COMPANY LIMITED) | | | | | | | |
| | nitrogen-containing aromatic compound | | | | | | | |
| Solvent | 1-Methoxy-2-propyl acetate | 39.46 | 41.94 | 39.44 | 39.44 | 5.70 | 3.61 | 35.26 |
| | Methyl ethyl ketone | 38.50 | 36.00 | 38.50 | 38.50 | 45.00 | 45.00 | 42.60 |

| | | | | | | | |
|---|---|---|---|---|---|---|---|
| Total (parts by mass) | 100 | 100 | 100 | 100 | 100 | 100 | 100 |

### Examples 1 to 8, and Comparative Example 1

A LUMIRROR 16KS40 temporary support (thickness of 16 μm, manufactured by Toray Industries, Inc., a polyethylene terephthalate film) was coated with each photosensitive composition described in Table 1 by using a slit-shaped nozzle, and the solvent was then volatilized in a drying zone at 100° C. to form a photosensitive layer. The coating amount of each photosensitive composition was adjusted to be a thickness of each photosensitive layer shown in Table 2. Next, each of photosensitive transfer materials in Examples 1 to 20 and 22 to 42, and Comparative Example 1 was produced in such a manner that a protective film (LUMIRROR 16KS40, thickness of 16 μm, manufactured by Toray Industries, Inc., polyethylene terephthalate film) was laminated on the above-described photosensitive layer with a laminating machine at 50° C. and a pressure of 0.5 MPa. Each of the above-described photosensitive transfer materials has a temporary support, a photosensitive layer, and a protective film in this order.

Preparation of Patterning Resist

5.63 parts by mass of Compound (P-1) (solid content of 27.0% by mass, PGMEA solution), 1.59 parts by mass of KAYARAD DPHA (manufactured by Nippon Kayaku Co., Ltd.), 0.159 parts by mass of IRGACURE 379 (manufactured by BASF SE), 0.150 parts by mass of EHPE-3150 (manufactured by Daicel Corporation), 0.002 parts by mass of MEGAFACE F781F (manufactured by DIC Corporation), and 17.5 parts by mass of PGMEA were added and stirred to prepare a patterning resist composition.

Production of Patterning Resist Transfer Material

A LUMIRROR 16KS40 temporary support (thickness of 16 μm, manufactured by Toray Industries, Inc., a polyethylene terephthalate film) was coated with the patterning resist composition so that a film thickness after drying is 5 μm by using a slit-shaped nozzle, and the solvent was then volatilized in a drying zone at 120° C. to form a patterning resist layer. Next, a protective film (LUMIRROR 16KS40, thickness of 16 μm, manufactured by Toray Industries, Inc., polyethylene terephthalate film) was laminated on the above-described photosensitive layer with a laminating machine at 50° C. and a pressure of 0.5 MPa to produce a patterning resist transfer material. The transfer material includes a temporary support, a patterning resist layer, and a protective film in this order.

Preparation of Coating Liquid for Forming Silver Nanowire Layer

Preparation of Additive Solution A

0.51 g of silver nitrate powder was dissolved in 50 mL of pure water. 1 mol/L of aqueous ammonia was added to the obtained solution until the liquid became transparent. Thereafter, pure water was added to the obtained solution so that the total amount of the solution became 100 mL to prepare an additive solution A.

Preparation of Additive Solution G

0.5 g of glucose powder was dissolved in 140 mL of pure water to prepare an additive solution G

Preparation of Additive Solution H

0.5 g of hexadecyl-trimethylammonium bromide (HTAB) powder was dissolved in 27.5 mL of pure water to prepare an additive solution H.

Preparation of Coating Liquid for Forming Silver Nanowire Layer

After putting pure water (410 mL) into a three-neck flask, the additive solution H (82.5 mL) and the additive solution G (206 mL) were added thereto with a funnel while stirring at 20° C. The additive solution A (206 mL) was added to the obtained solution at a flow rate of 2.0 mL/min and a stirring rotation speed of 800 rpm (revolutions per minutes; the same applies hereinafter). After 10 minutes, 82.5 mL of the additive solution H was added to the obtained solution. Thereafter, the obtained solution was heated to an internal temperature of 75° C. at 3 ° C./min. Thereafter, the stirring rotation speed was reduced to 200 rpm, and the solution was heated for 5 hours. After cooling the obtained solution, the solution was placed in a stainless steel cup, and ultrafiltration was performed using an ultrafiltration device in which an ultrafiltration module SIP1013 (manufactured by Asahi Kasei Corporation, molecular weight cut off: 6,000), a magnet pump, a stainless steel cup was connected with a silicon tube. In a case where the filtrate from the module reached 50 mL, 950 mL of distilled water was added to the stainless steel cup for washing. After repeating the above-described washing 10 times, concentration was performed until the amount of the solution reached 50 mL. The additive solution A, the additive solution G, and the additive solution H were repeatedly produced by the above-described method and used for preparing a coating liquid for forming a silver nanowire layer.

0.08% by mass of hydroxypropylmethylcellulose was added to the obtained concentrated solution, per 0.36% by mass of silver nanowires, and pure water was added so that the amount of pure water was 99.56% by mass. Thereafter, the mixture was dispersed at 80° C. with stirring for 30 minutes, thereby obtaining a coating liquid for forming a silver nanowire layer.

Measurement of Diameter and Major Axis Length of Silver Nanowires

300 silver nanowires were observed by using a transmission electron microscope (TEM; JEM-2000FX, manufactured by JEOL Ltd.), and a diameter and a major axis length of each silver nanowire were measured. The diameter and the major axis length of the silver nanowire were calculated by arithmetically averaging 300 measured values. As a result, the diameter of the silver nanowire was 17 nm, the major axis length thereof was 35 μm.

Production of Transparent Conductive Film

Next, the coating liquid for forming a silver nanowire layer was applied to a cycloolefin polymer film. The amount of the coating liquid for forming a silver nanowire layer was set so that the wet film thickness was 20 μm. The layer thickness of the silver nanowire layer after drying was 30 nm, and the sheet resistance of the layer including the silver nanowire was 60 Ω/□. The sheet resistance was measured using a noncontact eddy current-type resistance measuring instrument EC-80P (manufactured by Napson Corporation).

A copper film was formed on the silver nanowire layer side of the substrate by a sputtering method to have a thickness of 200 nm to produce a transparent conductive film having a laminated structure composed of the copper film/the silver nanowire layer/the cycloolefin polymer film.

Resist Patterning Step

Regarding the patterning resist transfer material, the protective film was peeled off, a surface of the patterning resist layer exposed was laminated on the copper film side of the transparent conductive film produced above to obtain a laminate having a structure composed of the temporary support/patterning resist layer/copper film/silver nanowire layer/cycloolefin polymer film. In the laminating conditions, a roll temperature was set as 110° C., a linear pressure was set as 0.6 MPa, and a linear velocity (laminating speed) was set as 2.0 m/min. A proximity type exposure machine (manufactured by Hitachi High-Tech Electronic Engineering Corporation) having an ultra-high pressure mercury lamp was used to expose the laminate described above with an exposure amount of 60 mJ/cm² (i ray), without peeling off the temporary support. After the exposure, the laminate was left to stand for 1 hour, the temporary support was peeled off, and shower development was carried out for 60 seconds with a 2.38% tetramethylammonium hydroxide aqueous solution. The shower pressure was 0.04 MPa. After rinsing with a pure water shower, the drying was carried out at 50° C. for 1 minute to produce a transparent conductive film with a resist pattern.

An exposure mask with a lead-out electrode part of 2 mm×10 mm, an electrode thin line portion of a line/space of 200/30 μm, and a thin line length of 80 mm was employed.

Copper Film/Silver Nanowire Etching Step

The transparent conductive film with a resist pattern was immersed in a 10.0% ammonium sulfate aqueous solution at 30° C. for 2 minutes, etched, and rinsed with a pure water shower, and the resultant film was then immersed in an etchant containing 1% HNO₃, 1% NaNO₃, and 5 ppm KMnO₄ at 25° C. for 2 minutes, etched, rinsed with a pure water shower, and dried at 120° C. for 1 minute to produce with an etched transparent conductive film patterned with a resist pattern.

Resist Peeling Step

The etched transparent conductive film with a resist pattern was immersed in a 2.38% tetramethylammonium hydroxide aqueous solution for 75 seconds to peel the resist, rinsed with a pure water shower, and dried at 50° C. for 1 minute, thereby producing a patterning transparent conductive film A.

Resist Patterning Step 2

Regarding the patterning resist transfer material, the protective film was peeled off, a surface of the patterning resist layer exposed was laminated on the copper film remaining side of the patterning transparent conductive film A produced above to obtain a laminate having a structure composed of the temporary support/photosensitive layer/copper film/silver nanowire layer/cycloolefin polymer film. In the laminating conditions, a roll temperature was set as 110° C., a linear pressure was set as 0.6 MPa, and a linear velocity (laminating speed) was set as 2.0 m/min. A proximity type exposure machine (manufactured by Hitachi High-Tech Electronic Engineering Corporation) having an ultra-high pressure mercury lamp was used to expose the laminate described above with an exposure amount of 60 mJ/cm² (i ray), without peeling off the temporary support. After the exposure, the laminate was left to stand for 1 hour, the temporary support was peeled off, and shower development was carried out for 60 seconds with a 2.38% tetramethylammonium hydroxide aqueous solution. The shower pressure was 0.04 MPa. After rinsing with a pure water shower, the drying was carried out at 50° C. for 1 minute to produce a transparent conductive film with a resist pattern B.

An exposure mask with a lead-out electrode part that has a size of 2 mm×10 mm and that is vacant.

Copper Film Etching Step

The transparent conductive film with a resist pattern was immersed in a 10.0% ammonium sulfate aqueous solution at 30° C. for 2 minutes, etched, rinsed with a pure water shower, and dried at 120° C. for 1 minute to produce an etched transparent conductive film B patterned with a resist pattern.

Resist Peeling Step 2

The etched transparent conductive film B with a resist pattern was immersed in a 2.38% tetramethylammonium hydroxide aqueous solution for 75 seconds to peel the resist, rinsed with a pure water shower, and dried at 50° C. for 1 minute, thereby producing a patterning transparent conductive film B.

Production of Laminate

Regarding each of the photosensitive transfer materials of Examples 1 to 8, the protective film was peeled off, a surface of the photosensitive layer exposed was laminated on the copper film/silver nanowire layer side of the patterning transparent conductive film B produced above to obtain a laminate having a structure composed of the temporary support/photosensitive layer/copper film/silver nanowire layer/cycloolefin polymer film. In the laminating conditions, a roll temperature was set as 110° C., a linear pressure was set as 0.6 MPa, and a linear velocity (laminating speed) was set as 2.0 m/min. Each laminate was left to stand for 3 hours, a proximity type exposure machine (manufactured by Hitachi High-Tech Electronic Engineering Corporation) having an ultra-high pressure mercury lamp was used to expose each laminate with an exposure amount of 60 mJ/cm² (i ray) through a mask having an opening portion with a width of 80 mm, without peeling off the temporary support. After exposure, the temporary support of each laminate described above was peeled off after being left to stand for 3 hours, developed for 45 seconds with a 1% by mass aqueous solution of sodium carbonate (liquid temperature of 30° C.), rinsed with a pure water shower, and dried at 75° C. for 13 seconds to develop and remove the photosensitive layer in the unexposed portion. The laminate was further exposed with an exposure amount of 375 mJ/cm² (i ray), and the photosensitive layer was cured. Thereafter, post-baking treatment was carried out at 145° C. for 30 minutes to produce each laminate.

Regarding the photosensitive transfer material of Comparative Example 1, the protective film was peeled off, a surface of the photosensitive layer exposed was laminated on the copper film/silver nanowire layer side of the patterning transparent conductive film B produced above to obtain a laminate having a structure composed of the temporary support/photosensitive layer/copper film/silver nanowire layer/cycloolefin polymer film. In the laminating conditions, a roll temperature was set as 110° C., a linear pressure was set as 0.6 MPa, and a linear velocity (laminating speed) was set as 2.0 m/min. Each laminate was left to stand for 3 hours, a proximity type exposure machine (manufactured by Hitachi High-Tech Electronic Engineering Corporation) having an ultra-high pressure mercury lamp was used to expose each laminate with an exposure amount of 60 mJ/cm² (i ray) through a mask having an opening portion with a width of 80 mm, without peeling off the temporary support. After exposure, the temporary support of each laminate described above was peeled off after being left to stand for 3 hours, developed for 45 seconds with a 1% by mass aqueous solution of sodium carbonate (liquid temperature of 30° C.), rinsed with a pure water shower, and dried at 75° C. for 13 seconds to develop and remove the photosensitive layer in the unexposed portion. The laminate was further exposed with an exposure amount of 375 mJ/cm² (i ray) to cure the photosensitive layer, and a laminate of Comparative Example 1 was produced.

Migration Resistance Test

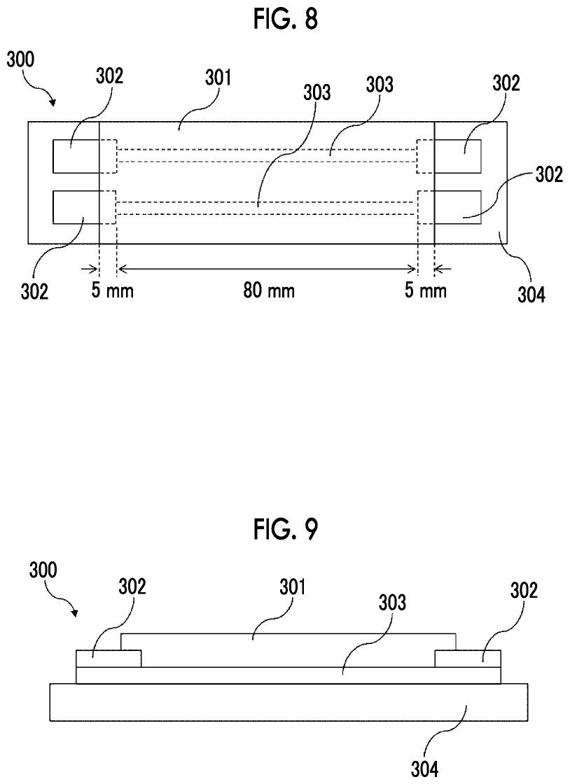

The laminate produced as described above was used to evaluate migration resistance as follows. A schematic plane view and a schematic cross-sectional view of a laminate 300 used in the migration resistance test are shown in FIGS. 8 and 9, respectively. The laminate 300 includes a resin layer 301, a lead-out electrode part 302, a silver nanowire layer 303, and a substrate 304.

Wiring resistance values of anode and cathode were measured by using a contact-type resistance measuring instrument RM3548 (manufactured by HIOKI E.E. CORPORATION). That is, a probe of the resistance measuring instrument was pressed against the lead-out electrode part 302 of the laminate produced above to be closely attached, and resistance values were measured.

A power supply PM18-2 (manufactured by Kenwood Corporation) was connected to anode and cathode of the produced laminate. That is, an anode terminal of the power supply was connected to the lead-out electrode part of the anode of the laminate produced above, and a cathode terminal was connected to the lead-out electrode part of the cathode so as to be in close contact with each other. The laminate that has been connected to the power supply was tested by using a thermo-hygrostat for 500 hours at a temperature of 65° C., a humidity of 90% RH, and a direct current voltage of 5 V. Wiring resistance values of the anode were measured before and after the moisture-heat test, and evaluation was carried out according to the following evaluation standard of the following A to D depending on a rate of change of the wiring resistance values before and after the test. The rate of change was calculated by subtracting the wiring resistance value before the test from the wiring resistance value after the test and dividing the absolute value of the amount of change in the wiring resistance value by the wiring resistance value before the test. A to C are acceptable ranges.

A: Rate of change was 0% or more and 5% or less.

B: Rate of change was more than 5% and 10% or less.

C: Rate of change was more than 10% and 20% or less.

D: Rate of change was more than 20%.

TABLE 2

| | Photo- | | Compound A causing | Migra- |
|---|---|---|---|---|
| | sensitive | Thick- | decrease in hydrophilic | tion re- |
| | composition | ness | group | sistance |
| Example 1 | A-1 | 5 μm | AOI-SM | A |
| Example 2 | A-1 | 10 μm | AOI-SM | A |
| Example 3 | A-1 | 3 μm | AOI-SM | A |
| Example 4 | A-2 | 5 μm | Celoxide | A |
| | | | 2021P | |
| Example 5 | A-3 | 5 μm | ARONE | A |
| | | | OXETANE | |
| | | | OXT-221 | |
| Example 6 | A-4 | 5 μm | DVE-3 (triethylene | A |
| | | | glycol divinyl ether) | |
| Example 7 | A-5 | 5 μm | 1-Methyl- | A |
| | | | isoquinoline | |
| Example 8 | A-6 | 5 μm | 1-Methyl- | A |
| | | | isoquinoline | |
| Comparative | A-7 | 5 μm | None | D |
| Example 1 | | | | |

### EXPLANATION OF REFERENCES

10: photosensitive transfer material

12: temporary support

16: protective film

18, 18A: photosensitive layer (metal conductive material protective film, resin layer)

20: antistatic layer

32: substrate

56: lead wire

70: first metal conductive material

72: second metal conductive material

74: image display region

75: image non-display region

90: touch panel

112: first island-shaped electrode portion

114: second island-shaped electrode portion

116: first wiring portion

118: second wiring portion (bridge wiring)

120: through-hole

124: transparent substrate (transparent film substrate)

130: protective layer

132: overcoat layer

134: first electrode pattern

136: second electrode pattern

200: transparent laminate

300: laminate

301: resin layer

302: lead-out electrode part

303: silver nanowire layer

304: substrate

P: extension direction of first electrode pattern

Q: extension direction of second electrode pattern

What is claimed is:

1. A film comprising:
a metal-containing layer; and
a resin layer that comprises a binder polymer and a compound A and that is disposed on a surface of the metal-containing layer,
a number of hydrophilic groups in the compound A being decreased by an action of light or heat.

2. The film according to claim 1, wherein the compound A is a blocked isocyanate compound or an isocyanate compound.

3. The film according to claim 1, wherein the compound A is a cationically polymerizable compound.

4. The film according to claim 1, wherein the compound A has a structure capable of receiving an electron from an acid group.

5. The film according to claim 1, wherein the compound A having the structure capable of receiving an electron from an acid group is a nitrogen-containing aromatic compound.

6. The film according to claim 1, wherein the metal-containing layer comprises a silver nanowire and a hydrophilic compound.

7. The film according to claim 6, wherein the hydrophilic compound comprises a hydroxyl group or an acid group.

8. A touch panel comprising the film according to claim 1.

9. A laminate comprising the film according to claim 1, the laminate comprising, in the following order:
a substrate having the metal-containing layer on its surface; and
the resin layer.
